(19) United States
(12) Patent Application Publication
(10) Pub. No.: US 2026/0239860 A1
(43) Pub. Date: Aug. 13, 2026

(54) LIGHT EMITTING DISPLAY DEVICE AND ELECTRONIC DEVICE

(71) Applicant: Samsung Display Co., Ltd., Yongin-si (KR)

(72) Inventors: Kook Hyun CHOI, Yongin-si (KR); Changwook KIM, Yongin-si (KR); Seon Uk LEE, Yongin-si (KR); Jin Su LEE, Yongin-si (KR); Yechan CHOI, Yongin-si (KR)

(73) Assignee: Samsung Display Co., Ltd., Yongin-si (KR)

(21) Appl. No.: 19/338,210

(22) Filed: Sep. 24, 2025

(30) Foreign Application Priority Data
Feb. 11, 2025 (KR) 10-2025-0017499
May 14, 2025 (KR) 10-2025-0062599

(51) Int. Cl. H10K 59/80; H10K 59/126; H10K 59/38; H10K 102/00

(52) U.S. Cl. CPC H10K 59/877; H10K 59/126; H10K 59/38; H10K 2102/331

(57) ABSTRACT

A light emitting display device includes a substrate, an anode on the substrate, a pixel defining layer including a first opening above the anode, a light emitting layer in the first opening, a cathode on the light emitting layer and the pixel defining layer, an encapsulation layer on the cathode, a scattering layer on the encapsulation layer, the scattering layer including scattering particles, and a scattering layer opening that at least partially overlaps the first opening in plan view, and a light blocking layer including a second opening that overlaps the first opening in plan view, where, in plan view, a width of the scattering layer opening is smaller than a width of the second opening by 1 µm or more, and the width of the scattering layer opening is smaller than a width of the first opening by 10 µm or less.

### CROSS-REFERENCE TO RELATED APPLICATION

This application is based on claims priority to Korean Patent Application No. 10-2025-0017499, filed on February 11, 2025, in the Korean Intellectual Property Office, and Korean Patent Application No. 10-2025-0062599, filed on May 14, 2025, in the Korean Intellectual Property Office, the disclosures of which are incorporated by reference herein in their entireties.

### BACKGROUND

### Field

The present disclosure relates to a light emitting display device and an electronic device.

### Description of the Related Art

A display device is a device for displaying an image, and may include a liquid crystal display (LCD), an organic light emitting diode (OLED) display, and the like. The display device is used in various electronic devices such as mobile phones, navigation devices, digital cameras, electronic books, portable game machines, and various terminals.

A display device such as an organic light emitting display device may have a structure that may be bent or folded by using a flexible substrate.

In addition, in small electronic devices such as mobile phones, optical elements such as camera sensors and optical sensors may be formed in a bezel area around a display area, but as the size of the display area increases while the size of a peripheral area of the display area gradually decreases, technologies are being developed that allow cameras or optical sensors to be disposed on a rear surface of the display area.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a light emitting display device that may eliminate rainbow mura (or rainbow spots) occurring in a light emitting display device including a scattering layer.

Additional aspects will be set forth in part in the description which follows and, in part, will be apparent from the description, or may be learned by practice of the presented embodiments.

According to an aspect of the disclosure, a light emitting display device may include a substrate, an anode on the substrate, a pixel defining layer including a first opening above the anode, a light emitting layer in the first opening, a cathode on the light emitting layer and the pixel defining layer, an encapsulation layer on the cathode, a scattering layer on the encapsulation layer, the scattering layer including scattering particles, and a scattering layer opening that at least partially overlaps the first opening in plan view, and a light blocking layer including a second opening that overlaps the first opening in plan view, where, in plan view, a width of the scattering layer opening is smaller than a width of the second opening by 1 µm or more, and the width of the scattering layer opening is smaller than a width of the first opening by 10 µm or less.

In plan view, the first opening, the scattering layer opening, and the second opening may be circular.

In plan view, the first opening, the scattering layer opening, and the second opening may be elliptical.

A major axis direction of the scattering layer opening may match major axis directions of the first opening and the second opening.

In plan view, the width of the scattering layer opening may be equal to the width of the first opening.

The scattering layer may include an inner opening in which the scattering layer is not formed in a portion where the light blocking layer is provided.

The scattering layer may include a sidewall that protrudes at an acute angle toward a front surface of the light emitting display device and a taper angle of the scattering layer may be less than 90 degrees.

According to an aspect of the disclosure, a light emitting display device may include a substrate, an anode on the substrate, a pixel defining layer including a first opening above the anode, a light emitting layer in the first opening, a cathode on the light emitting layer and the pixel defining layer, an encapsulation layer on the cathode, a scattering layer on the encapsulation layer, the scattering layer including scattering particles and a scattering layer opening that at least partially overlaps the first opening in plan view, and a plurality of color filters on the scattering layer and respectively corresponding to different colors, where at least two of the plurality of color filters overlap, the light emitting display device includes a second opening that overlaps the first opening and in which only one of the plurality of color filters is provided, and in plan view, a width of the scattering layer opening is smaller than a width of the second opening by 1 µm or more, and the width of the scattering layer opening is smaller than a width of the first opening by 10 µm or less.

In plan view, the first opening, the scattering layer opening, and the second opening may be circular.

In plan view, the first opening, the scattering layer opening, and the second opening may be elliptical.

A major axis direction of the scattering layer opening may match major axis directions of the first opening and the second opening.

In plan view, the width of the scattering layer opening may be equal to the width of the first opening match.

The scattering layer may include an inner opening in which the scattering layer is not formed in a portion where a light blocking area of the plurality of color filters is disposed.

The scattering layer may include a sidewall that protrudes at an acute angle toward a front surface of the light emitting display device and a taper angle of the scattering layer may be less than 90 degrees.

According to an aspect of an example embodiment, an electronic device may include a light emitting display device configured to display an image. The light emitting display device may include a substrate, an anode on the substrate, a pixel defining layer inducing a first opening above the anode, a light emitting layer in the first opening, a cathode on the light emitting layer and the pixel defining layer, an encapsulation layer on the cathode, a scattering layer on the encapsulation layer, the scattering layer including scattering particles, and a scattering layer opening that at least partially overlaps the first opening in plan view, and a second opening that overlaps the first opening in plan view, where, in plan view, a width of the scattering layer opening is smaller than a width of the second opening by 1 µm or more, and the width of the scattering layer opening is smaller than a width of the first opening by 10 µm or less.

The electronic device may include a light blocking layer on the scattering layer and including the second opening.

The electronic device may include a plurality of color filters on the scattering layer and respectively corresponding to different colors, where at least two or more of the plurality of color filters overlap in a light blocking area of the plurality of color filters and only one of the plurality of color filters is in the second opening.

In plan view, the first opening, the scattering layer opening, and the second opening may be circular or elliptical.

The electronic device may include a light blocking layer including the second opening, where the scattering layer may include an inner opening in which the scattering layer is not formed in a portion where the light blocking layer is provided.

The scattering layer may include a sidewall that protrudes at an acute angle toward a front surface of the light emitting display device and a light blocking layer on the scattering layer and including the second opening.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a schematic perspective view of a use state of a display device according to an embodiment;

FIG. 2 is an exploded perspective view of a display device according to an embodiment;

FIG. 3 is a schematic cross-sectional view of a display device according to an embodiment;

FIG. 4 is a block diagram of a display device according to an embodiment;

FIG. 5 is a schematic perspective view of a light emitting display device according to an embodiment;

FIG. 6 is an enlarged plan view of a partial area of a light emitting display device according to an embodiment;

FIG. 7 is a schematic cross-sectional view of a display panel according to an embodiment;

FIG. 8 is a plan view of a portion of a display panel according to an embodiment;

FIG. 9 is a table comparing characteristics of a comparative example and three example embodiments;

FIG. 10 is a diagram illustrating an edge position of a scattering layer opening according in an embodiment;

FIG. 11 is a graph showing a relationship between an edge of a scattering layer opening and luminous efficiency;

FIG. 12 is a plan view of a portion of a display panel according to an embodiment;

FIG. 13 and FIG. 14 are tables comparing characteristics of comparative examples and example embodiments;

FIG. 15 and FIG. 16 are photographs of cross-sections of a portion of a display panel according to an embodiment;

FIG. 17 is a plan view of a portion of a display panel according to an embodiment;

FIG. 18 is a schematic cross-sectional view of a display panel according to the embodiment of FIG. 17;

FIG. 19 is a schematic cross-sectional view of a display panel according to an embodiment;

FIGS. 20, 21 and 22 are schematic cross-sectional views of a display panel according to an embodiment;

FIG. 23 is a graph showing transmittance of a color filter according to wavelength; and

FIGS. 24, 25, 26 and 27 are cross-sectional views of a light emitting display device according to an embodiment.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

Furthermore, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

As used herein, expressions such as “at least one of,” when preceding a list of elements, modify the entire list of elements and do not modify the individual elements of the list. For example, the expression, "at least one of a, b, and c," should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

In addition, unless explicitly stated to the contrary, the word “comprise,” and variations such as “comprises” and “comprising,” should be understood to imply the inclusion of stated elements but not the exclusion of any other elements.

Furthermore, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

In addition, throughout the specification, “connected” does not only mean when two or more elements are directly connected, but when two or more elements are indirectly connected through other elements, and when they are physically connected or electrically connected, and further, it may be referred to by different names depending on a position or function, and may also be referred to as a case in which parts that are substantially integrated are linked to each other.

In addition, throughout the specification, when it is said that an element such as a wire, layer, film, region, area, substrate, plate, or constituent element “is extending (or extends) in a first direction or second direction,” this does not mean only a straight shape extending straight in the corresponding direction, but may mean a structure that substantially extends in the first direction or the second direction, is partially bent, has a zigzag structure, or extends while having a curved structure.

In addition, both an electronic device (for example, a mobile phone, a television (TV), a monitor, a laptop computer, etc.) including a display device, or a display panel described in the specification, and an electronic device including a display device and a display panel manufactured by a manufacturing method described in the specification are not excluded from the scope of the present specification.

Terms such as first, second, etc. may be used to describe various components, but are used only for the purpose of distinguishing one component from another component. These terms do not limit the difference in the material or structure of the components.

The terms of a singular form may include plural forms unless otherwise specified. In addition, when a certain part “includes” a certain component, it means that other components may be further included rather than excluding other components unless otherwise stated. The use of the term “the” and similar designating terms may correspond to both the singular and the plural.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

The term “overlap” and its variants may indicate that one component extends over and covers at least a portion of another component in a particular direction, such as two components arranged vertically with respect to each other. Additionally, with reference to various openings, the term “overlap” and its variants may indicate that a portion of one opening extends over a portion of another opening, that one opening is above another opening without extensions of the upper opening (e.g., the width of an upper opening is within a width of a lower opening, etc.). As an example, when three openings are said to have an overlapping relationship, this may indicate that one opening has a largest width, one opening has a medium width, and one opening has a smallest width, and the openings are aligned such that the opening with the medium width and the opening with the smallest width are within the width of the opening with the largest width in plan view, in cross-sectional view, etc.. Furthermore, while a first component may be below a second component in a cross-sectional view, such first components may be described to overlap the second component in a plan view when at least a portion of the first component extends past at least a portion of the second component in the plan view. Other variations of the term “overlap” will be understood by one of ordinary skill in the art by reference to the drawings.

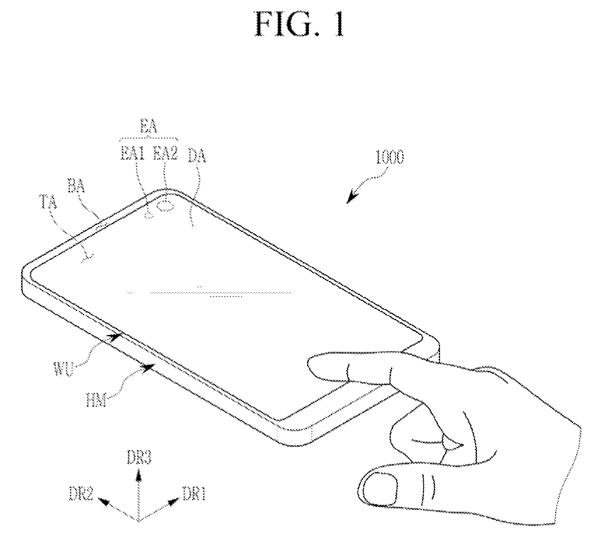

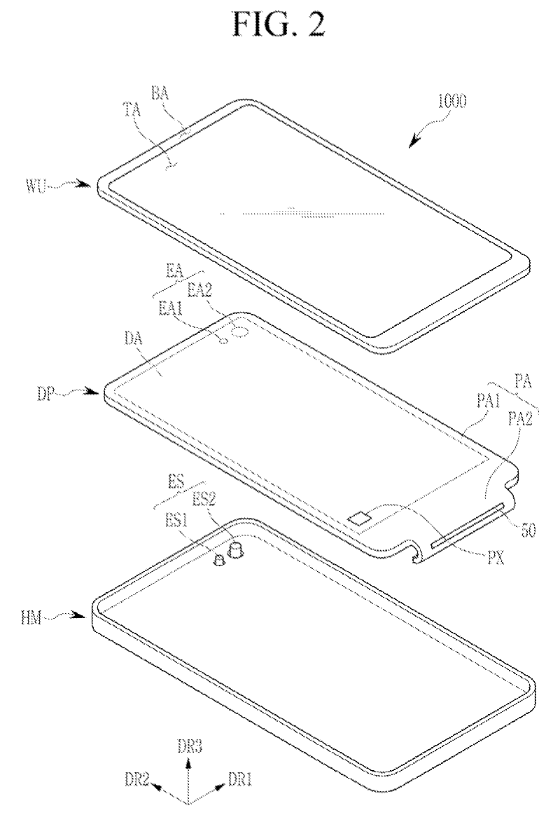

Hereinafter, a schematic structure of a display device will be described with reference to FIG. 1 and FIG. 2.

FIG. 1 is a schematic perspective view of a use state of a display device according to an embodiment, and FIG. 2 is an exploded perspective view of a display device according to an embodiment.

Referring to FIG. 1, a display device 1000 according to an embodiment is a device for displaying a moving image or a still image, and may be used as a display screen of a portable electronic device such as a mobile phone, a smart phone, a tablet personal computer (PC), a mobile communication terminal, an electronic notebook, an electronic book, a portable multimedia player (PMP), a navigation device, and an ultra-mobile PC (UMPC), and may be used as display screens of various products such as a television set, a laptop computer, a monitor, a billboard, or the Internet of things (IOT). In addition, the display device 1000 according to the embodiment may be used in a wearable device such as a smart watch, a watch phone, a glasses-type display, and a head mounted display (HMD). In addition, the display device 1000 according to the embodiment may be used as an instrument panel of a vehicle, a center information display (CID) disposed on a center fascia or dashboard of a vehicle, a room mirror display that replaces a side mirror of a vehicle, and a display disposed on the back of a front seat for entertainment for a rear seat of a vehicle. For better comprehension and ease of description, FIG. 1 illustrates a case in which the display device 1000 is used for a smart phone.

The display device 1000 may display an image toward a third direction DR3 on a display surface parallel to each of a first direction DR1 and a second direction DR2. A display surface on which an image is displayed may correspond to a front surface of the display device 1000, and may correspond to a front surface of a cover window WU. An image may include a static image as well as a dynamic image.

In the embodiment, a front (or top) surface and a rear (or bottom) surface of each member are defined based on a direction in which an image is displayed. The front and rear surfaces may be opposite to each other in the third direction DR3, and a normal direction of each of the front and rear surfaces may be parallel to the third direction DR3. A separation distance in the third direction DR3 between the front and rear surfaces may correspond to a thickness of a display panel in the third direction DR3.

The display device 1000 according to the embodiment may detect a user’s input (see hand of FIG. 1) applied from the outside. The user’s input may include various types of external inputs such as a part of the user’s body, light, heat, or pressure. In the embodiment, the user’s input is shown to be the user’s hand applied to the front surface. However, the present disclosure is not limited thereto. The user’s input may be variously provided, and the display device 1000 may sense the user’s input applied to the lateral or rear surface of the display device 1000 according to the structure of the display device 1000.

Referring to FIG. 1 and FIG. 2, the display device 1000 may include a cover window WU, a housing HM, a display panel DP, and an optical element ES. In the embodiment, the cover window WU and the housing HM may be combined to form an appearance of the display device 1000.

The cover window WU may include an insulating panel. For example, the cover window WU may be made of glass, plastic, or a combination thereof.

A front surface of the cover window WU may define the front surface of the display device 1000. A transmission area TA may be an optically transparent area. For example, the transmission area TA may be an area having visible ray transmittance of about 90% or more.

A blocking area BA may define a shape of the transmission area TA. The blocking area BA may be adjacent to the transmission area TA, and may surround the transmission area TA. The blocking area BA may be an area having relatively low light transmittance compared with the transmission area TA. The blocking area BA may include an opaque material that blocks light. The blocking area BA may have a predetermined color. The blocking area BA may be defined by a bezel layer provided separately from a transparent substrate defining the transmission area TA, or may be defined by an ink layer formed by being inserted into or coloring the transparent substrate.

The display panel DP may include a display pixel PX that displays an image and a driver 50, and the display pixel PX is disposed within a display area DA and a component area EA. The display panel DP may include a front surface that includes a display area DA and a non-display area PA. In the embodiment, the display area DA and the component area EA may be an area that includes a pixel and in which an image is displayed, and may be an area in which a touch sensor is disposed at an upper side of the pixel in the third direction DR3 to sense an external input.

The transmission area TA of the cover window WU may at least partially overlap the display area DA and the component area EA of the display panel DP. For example, the transmission area TA may overlap the front surface of the display area DA and the component area EA, or may overlap at least a portion of the display area DA and the component area EA. Accordingly, the user may view an image through the transmission area TA, or may provide an external input based on the image. However, the present disclosure is not limited thereto. For example, the area in which the image is displayed and the area in which the external input is detected may be separated from each other.

The non-display area PA of the display panel DP may at least partially overlap the blocking area BA of the cover window WU. The non-display area PA may be an area covered by the blocking area BA. The non-display area PA may be adjacent to the display area DA, and may surround the display area DA. No image is displayed in the non-display area PA, and a driving circuit or driving wire for driving the display area DA may be disposed therein. The non-display area PA may include a first peripheral area PA1 in which the display area DA is disposed at an outer side thereof, and a second peripheral area PA2 including the driver 50, a connection wire, and a bending area. In the embodiment of FIG. 2, the first peripheral area PA1 is disposed on three sides of the display area DA, and the second peripheral area PA2 is disposed on the other side of the display area DA.

In the embodiment, the display panel DP may be assembled in a flat state in which the display area DA, the component area EA and the non-display area PA facing the cover window WU. However, the present disclosure is not limited thereto. A portion of the non-display area PA of the display panel DP may be bent. In this case, a portion of the non-display area PA faces the rear surface of the display device 1000 so that the blocking area BA shown on the front surface of the display device 1000 may be reduced, and in FIG. 2, the second peripheral area PA2 is bent it may be assembled after being disposed on the rear surface of the display area DA.

In addition, the component area EA of the display panel DP may include a first component area EA1 and a second component area EA2. The first component area EA1 and the second component area EA2 may be at least partially surrounded by the display area DA. The first component area EA1 and the second component area EA2 are illustrated as being spaced apart from each other, but are not limited thereto, and may be partially connected. The first component area EA1 and the second component area EA2 may be areas in which optical elements (refer to ES of FIG. 2; also referred to as components hereinafter) that utilize infrared rays, visible light, or sound are disposed thereunder.

The display area DA (also referred to as a main display area hereinafter) and the component area EA are formed with a plurality of light emitting diodes and a plurality of pixel circuits that generate and transmit light emitting current to each of the plurality of light emitting diodes. Here, one light emitting diode and one pixel circuit portion are referred to as a pixel PX. In the display area DA and the component area EA, one pixel circuit portion and one light emitting diode may be formed one-to-one.

The first component area EA1 may include a transmitter through which light or/and sound may be transmitted and a display portion including a plurality of pixels. The transmitter is disposed between adjacent pixels, and is configured of a layer through which light or/and sound may be transmitted. The transmitter may be disposed between adjacent pixels, and in some embodiments, a layer that does not transmit light, such as a light blocking layer, may overlap the first component area EA1. The number of pixels (hereinafter also referred to as resolution) per unit area of the pixels (hereinafter also referred to as normal pixels) included in the display area DA may be the same as the number of pixels per unit area of the pixels (hereinafter also referred to as first component pixels) included in the first component area EA1.

The second component area EA2 includes an area (hereinafter also referred to as a light transmission area) configured of a transparent layer to allow light to pass through, and the light transmission area includes an opening in which a layer in which a conductive layer or a semiconductor layer is not disposed and that includes a light blocking material, for example, in which a pixel defining layer and/or a light blocking layer overlaps a position corresponding to the second component area EA2 so that it may have a structure that does not block light. The number of pixels per unit area of the pixels (hereinafter also referred to as second component pixels) included in the second component area EA2 may be smaller than the number of pixels per unit area of the normal pixels included in the display area DA. As a result, the resolution of the second component pixel may be lower than that of the normal pixel.

The display panel DP may further include a touch sensor TS in addition to the display area DA including the display pixel PX. The display panel DP may be viewed by the user from the outside through the transmission area TA, by including the pixel PX, which is a component that displays an image. In addition, the touch sensor TS may be disposed on the pixel PX, and may sense an input applied from the outside. The touch sensor TS may sense an external input provided to the cover window WU.

Referring back to FIG. 2, the second peripheral area PA2 may include a bending portion. The display area DA and the first peripheral area PA1 may have a flat state substantially parallel to a plane defined by the first direction DR1 and the second direction DR2, and one side of the second peripheral area PA2 may extend from the flat state through the bending portion to have a flat state again. As a result, at least a portion of the second peripheral area PA2 may be bent to be assembled to be disposed on the rear surface side of the display area DA. Since at least a portion of the second peripheral area PA2 overlaps the display area DA in a plan view when assembled, the blocking area BA of the display device 1000 may be reduced. However, the present disclosure is not limited thereto. For example, the second peripheral area PA2 may not be bent.

The driver 50 may be mounted on the second peripheral area PA2, mounted on the bending portion, or disposed on either side of the bending portion. The driver 50 may be provided in a form of a chip.

The driver 50 may be electrically connected to the display area DA and the component area EA to transmit electrical signals to pixels of the display area DA and the component area EA. For example, the driver 50 may provide data signals to pixels PX disposed in the display area DA. Alternatively, the driver 50 may include a touch driving circuit, and may be electrically connected to the touch sensor TS disposed in the display area DA and/or the component area EA. The driver 50 may include various circuits in addition to the above-described circuits, or may be designed to provide various electrical signals to the display area DA.

A pad portion may be disposed at an end of the second peripheral area PA2, and the display device 1000 may be electrically connected to a flexible printed circuit board (FPCB) including a driving chip by the pad portion. Here, the driving chip disposed on the flexible printed circuit board may include various driving circuits for driving the display device 1000 or connectors for supplying of power. In some embodiments, instead of the flexible printed circuit board, a rigid printed circuit board (PCB) may be used.

The optical element ES may be disposed under the display panel DP. The optical element ES may include a first optical element ES1 corresponding to the first component area EA1 and a second optical element ES2 corresponding to the second component area EA2. The first optical element ES1 may also utilize infrared light, in which case the first component area EA1 may overlap a layer that does not transmit light such as a light blocking layer.

In some embodiments, the first optical element ES1 may be replaced by an electronic element utilizing light or sound. For example, instead of the first optical element ES1, it may be a sensor that receives and uses light such as an infrared sensor, a sensor that outputs and detects light or sound to measure a distance or recognize a fingerprint, a small-sized lamp that outputs light, a speaker that outputs sound, and the like. In a case of an electronic element using light, light of various wavelength bands such as visible light, infrared light, and ultraviolet light may be used.

The second optical element ES2 may be at least one of a camera, an infrared (IR) camera, a dot projector, an infrared illuminator, and a time-of-flight (ToF) sensor.

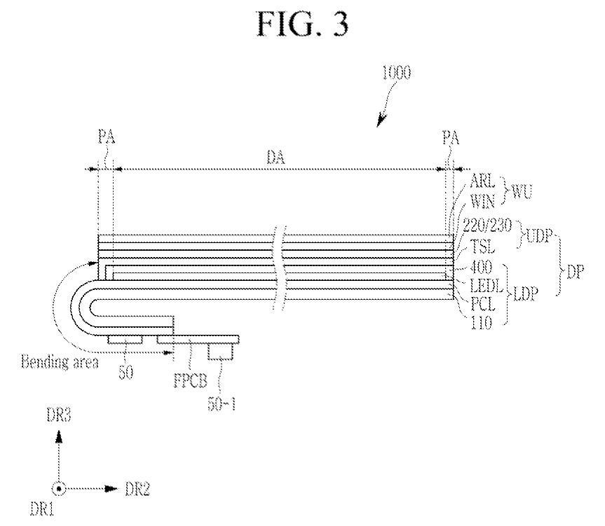

The light emitting display device as described above may have a cross-sectional structure as shown in FIG. 3, and the cross-sectional structure will be described through FIG. 3.

FIG. 3 is a schematic cross-sectional view of a display device according to an embodiment.

Referring to FIG. 3, the light emitting display device 1000 includes a display panel DP divided into a lower panel layer LDP and an upper panel layer UDP, and a cover window WU disposed on a front surface of the display panel.

The lower panel layer LDP of the display panel DP includes a light emitting element layer LEDL in which light emitting diodes forming pixels PX are disposed on a substrate 110, and a pixel circuit layer PCL in which a pixel circuit portion for transmitting current to the light emitting diodes disposed in the light emitting element layer LEDL is disposed, and the pixel circuit layer PCL may be located between the substrate 110 and the light emitting element layer LEDL. The lower panel layer LDP further includes an encapsulation layer 400, and the light emitting element layer LEDL is covered by the encapsulation layer 400. Due to the encapsulation layer 400, moisture and air are prevented from flowing into the light emitting element layer LEDL, thereby protecting the light emitting element layer LEDL.

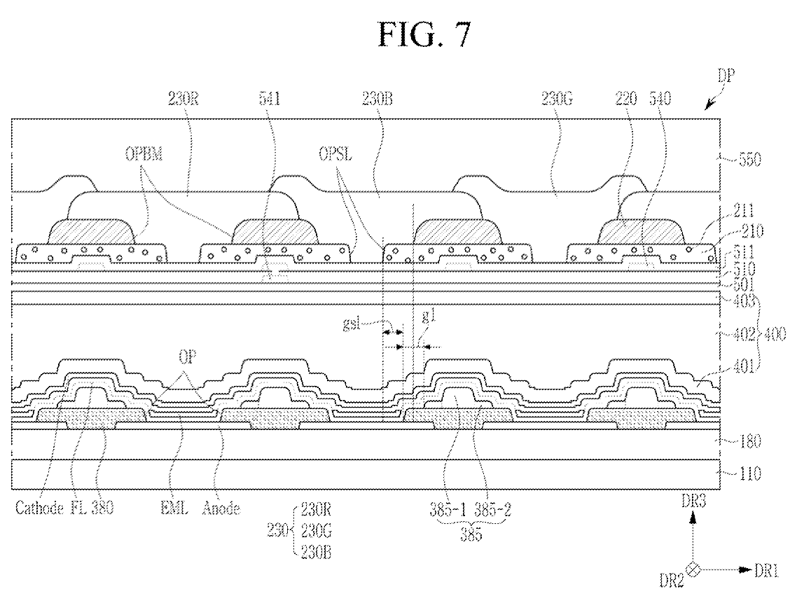

The upper panel layer UDP of the display panel DP may include a touch sensing layer TSL and a light blocking layer and color filter layer 220/230. The touch sensing layer TSL may include a sensing insulating layer (refer to 501, 510, and 511 of FIG. 7) and a plurality of sensing electrodes (refer to 540 and 541 of FIG. 7). The light blocking layer and color filter layer 220/230 include a light blocking layer (refer to 220 of FIG. 7) and a color filter (refer to 230 of FIG. 7), and a scattering layer (refer to 210 of FIG. 7) may also be disposed therein.

Specifically, each structure may be as follows.

The substrate 110 is a base substrate or a base member, and may be a flexible substrate capable of bending, folding, rolling, and the like. For example, the substrate 110 may include a polymer resin such as polyimide PI, but is not limited thereto. In some embodiments, the substrate 110 may include a glass material or a metal material.

The pixel circuit layer PCL may be disposed on the substrate 110. The pixel circuit layer PCL may include a plurality of thin-film transistors configuring a pixel circuit portion of the pixels PX, and may additionally include a capacitor. The pixel circuit layer PCL may include wiring connected to the pixel circuit portion, such as scan lines, data lines, and power voltage lines. Each of the thin-film transistors may include a semiconductor region, a source electrode, a drain electrode, and a gate electrode. The pixel circuit layer PCL may be disposed in the display area DA, and in some embodiments, may also be disposed in a portion of a non-display area PA or a portion of a bending area.

The light emitting element layer LEDL may be disposed on the pixel circuit layer PCL. The light emitting element layer LEDL may include a plurality of light emitting diodes for emitting light, including an anode, a cathode, and a light emitting layer, and a pixel defining layer defining a light emitting region. A plurality of light emitting elements of the light emitting element layer LEDL may be disposed in the display area DA.

In the embodiment, the light emitting layer may be an organic light emitting layer including an organic material. At least one of functional layers such as a hole transport layer, a hole injection layer, an electron transport layer, and an electron injection layer, may be included above and below the light emitting layer. When current flows between the anode and the cathode, holes and electrons may be moved to the light emitting layer through the hole transport layer and the electron transport layer, respectively, and may combine with each other in the light emitting layer to emit light.

In some embodiments, the light emitting element may include a quantum dot light emitting diode including a quantum dot light emitting layer, an inorganic light emitting diode including an inorganic semiconductor, or a micro-light emitting diode.

The encapsulation layer 400 may cover an upper surface and side surfaces of the light emitting element layer LEDL and protect the light emitting element layer LEDL. The encapsulation layer 400 may include at least one inorganic layer and at least one organic layer for encapsulating the light emitting element layer LEDL.

The touch sensing layer TSL may be disposed on the encapsulation layer 400. The touch sensing layer TSL may include a plurality of sensing electrodes for sensing the user’s touch by a capacitance method, and a plurality of sensing lines connecting the plurality of sensing electrodes to a touch driver 50-1. In some embodiments, the touch sensing layer TSL may sense the user’s touch by a mutual capacitance method or a self-capacitance method.

In some embodiments, the touch sensing layer TSL may be formed on a separate substrate disposed on the light emitting element layer LEDL. In this case, the substrate supporting the touch sensing layer TSL may serve as an encapsulation substrate for encapsulating the light emitting element layer LEDL, and the encapsulation layer 400 may be omitted when the encapsulation substrate is disposed.

The plurality of sensing electrodes of the touch sensing layer TSL may not overlap the light emitting region and may be disposed so as to be covered by a light blocking layer or the like, which will be described later.

The light blocking layer and color filter layer 220/230 are disposed on the touch sensing layer TSL and may include a light blocking layer (refer to 220 in FIG. 7) and a color filter (refer to 230 in FIG. 7). Additionally, in some embodiments, a scattering layer (refer to 210 in FIG. 7) may be disposed. The light blocking layer covers the sensing electrode and may be in such a position that it does not overlap the light emitting region, and the color filter may overlap a corresponding light emitting region for each color, thereby improving the color of light emitted from the light emitting diode.

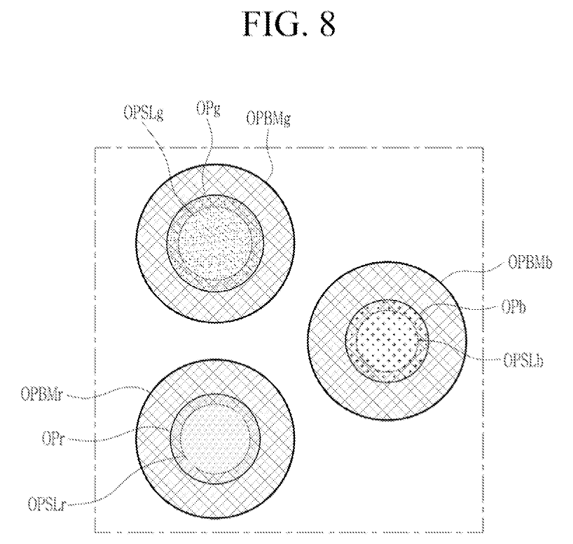

The light blocking layer and color filter layer 220/230 may have a structure that reduces reflection of external light so that external light entering the display device 1000 is not reflected back and transmitted to a user’s eyes. This will be described in more detail with reference to FIG. 8 and the like.

The substrate 110 may include a bending area and have a folded structure toward a rear surface, and the driver 50 may be disposed on one surface of the folded substrate 110, and the substrate 110 may be electrically connected to a flexible printed circuit board FPCB having a touch driver 50-1 attached thereto.

Here, the driver 50 may output signals and voltages for driving the display panel DP. The driver 50 may supply data voltages to a plurality of data lines, supply each power voltage to a power line such as a driving voltage line, and supply control signals such as clock signals so that scan signals to be applied to scan lines may be generated. The driver 50 may be formed as an integrated circuit (IC) and mounted on the display panel DP by a chip-on-glass (COG) method, a chip-on-plastic (COP) method, or an ultrasonic bonding method. For example, the driver 50 may be disposed in an opposite direction to the display area DA and the third direction DR3 by bending the substrate 110 and may be disposed on the back surface of the display area DA. In some embodiments, the driver 50 may be mounted on the flexible printed circuit board FPCB.

The flexible printed circuit board FPCB may be attached to the pad portion of the display panel DP using an anisotropic conductive film (ACF). The pad portion of the flexible printed circuit board FPCB may be electrically connected to the pad portion of the display panel DP. The flexible printed circuit board FPCB may be a flexible printed circuit board, a printed circuit board, or a flexible film such as a chip-on-film.

The touch driver 50-1 may be mounted on the flexible printed circuit board FPCB. The touch driver 50-1 may be electrically connected to sensing electrodes of the touch sensing layer TSL of the display panel DP, supply driving signals to a plurality of sensing electrodes, and detect a change in capacitance between the plurality of sensing electrodes to determine a touch input. The touch driver 50-1 may be formed as an integrated circuit (IC).

The cover window WU is disposed on a front surface of the display panel DP, and the cover window WU may include a window WIN and an anti-reflection layer ARL.

The window WIN may be disposed on the light blocking layer and color filter layer 220/230 and may be attached to the light blocking layer and color filter layer 220/230 by a transparent adhesive. The window WIN may function to protect the display panel DP. The window WIN may be made of a transparent material. The window WIN may be made of, for example, glass or plastic.

When the window WIN includes glass, the glass may be ultra-thin glass (UTG) or thin film glass. The ultra-thin glass may be strengthened to have a predetermined stress profile internally. The strengthened ultra-thin glass better prevents crack generation due to external impact, crack propagation, and breakage than before being strengthened. The ultra-thin glass strengthened through a strengthening process may have different stresses in different areas.

When the glass is made of an ultra-thin film or a thin film, it may have flexible characteristics such that it may be bent, folded, or rolled. The thickness of the glass may be, for example, in the range of 10 µm to 300 µm, and specifically, glass with a thickness of 10 µm to 100 µm or about 50 µm may be applied. The glass of the window WIN may include soda lime glass, alkali aluminosilicate glass, borosilicate glass, or lithium alumina silicate glass. The glass of the window WIN may include chemically strengthened or thermally strengthened glass to provide high strength. Chemical strengthening may be performed through an ion exchange treatment process in an alkali salt. The ion exchange treatment process may be performed two or more times. Additionally, the window WIN may be a thin film of glass coated on both sides of a polymer film.

The anti-reflection layer ARL may be disposed on the front surface of the window WIN, and the anti-reflection layer ARL may be attached to the front surface of the window WIN in the form of an optical film.

The anti-reflection layer ARL may be disposed on the window WIN. The anti-reflection layer ARL may protect the window WIN and reduce the reflection of external light.

The anti-reflection layer ARL may include a hard coating layer and a low-refractive index layer, and due to the two layers having different refractive indices, it may be formed to cause loss of external light or destructive interference at the interface, thereby preventing or reducing the reflection of external light. Here, the low-refractive index layer may have a configuration including particles dispersed in a transparent resin. In some embodiments, a high-refractive index layer may be further included, and the high refractive index layer may be disposed between the hard coating layer and the low refractive index layer.

The hard coating layer, the low refractive index layer, and/or the high refractive index layer, which may be included in the anti-reflection layer ARL, may have the following characteristics.

The hard coating layer may improve reliability issues by reducing distortion or lifting of the anti-reflection layer ARL under harsh conditions such as high temperature or high humidity.

The hard coating layer may include an organic layer. The organic layer may include at least one or a combination of an acrylate-based compound, a urethane-based compound, a polyimide, a polycarbonate, a polyethersulfone, polyethylene naphthalate, polyphenylene sulfide, a liquid crystal polymer (LCP), polymethyl methacrylate, and an epoxy-based polymer.

In some embodiments, the hard coating layer may include an organic layer and an organic-inorganic composite layer. In this case, the organic layer may include an acrylate-based compound. For example, the organic layer may be formed to include urethane acrylate. The organic layer may serve as a stress buffer layer.

The organic material in the organic-inorganic composite layer may be formed from at least one or a combination of an acrylate-based compound, a polyurethane-based compound, and an epoxy-based compound. For example, the organic material may include urethane acrylate. The inorganic material in the organic-inorganic composite layer may be at least one selected from the group including silicon oxide (SiO₂), zirconium oxide (ZrO₂), aluminum oxide (Al₂O₃), tantalum oxide (Ta₂O₅), niobium oxide (Nb₂O₅ or NbO₂), and glass beads.

The inorganic material may be provided in the form of a single type of the inorganic oxides listed above or a mixture thereof. Additionally, the inorganic material may be provided in various forms to form an organic-inorganic composite layer. For example, silicon oxide may be provided in the form of particles, a sol, or a hollow shape.

In the organic-inorganic composite layer, the organic acrylate compound and the inorganic particles may be provided in a weight ratio of 5:5 to 8:2. By including both the acrylate compound and the inorganic particles, the organic-inorganic composite layer may form a hard coating layer that is resistant to breakage, having improved surface hardness while also being shock-absorbent against external impact.

In the embodiment, the hard coating layer may include an acrylate-based compound and a urethane-based compound. The acrylate-based compound and the urethane-based compound may be mixed in a monomer form and then polymerized. The acrylate-based compound may increase the hardness of a low refractive index layer, thereby increasing the hardness and wear resistance of the anti-reflection layer ARL. The urethane-based compound may provide flexibility to the low refractive index layer, thereby increasing the elasticity of the anti-reflection layer ARL. In this case, the ratio of the acrylate-based compound in the hard coating layer may be 70% to 99.9%, and the ratio of the urethane-based compound therein may be 0.1% to 30%. For example, the mixing ratio of the acrylate-based compound to the urethane-based compound may be 7:3 or more, and the ratio of the acrylate-based compound may be further increased. For example, the mixing ratio of the acrylate-based compound to the urethane-based compound may be further increased, such as 7:3, 8:2, or 9:1.

In some embodiments, the hard coating layer may include an acrylate-based compound. In this case, the acrylate-based compound may be an acrylic resin. That is, the hard coating layer may include an acrylic resin to improve the hardness and wear resistance of the anti-reflection layer (ARL).

The thickness of the hard coating layer may be 2 µm to 10 µm. By being formed within the aforementioned thickness range, the hard coating layer may reduce distortion and lifting phenomena, thereby improving reliability issues.

The refractive index of the hard coating layer may be 1.48 to 1.53. By being formed within the aforementioned refractive index range, the hard coating layer may have a refractive index difference at the interface with a low refractive index layer, described later, to refract light emitted from the light emitting element layer upwards, thereby increasing light emission efficiency and reducing reflection of external light.

The low refractive index layer may be disposed on the hard coating layer. The low refractive index layer may refract light emitted from the light emitting element layer upwards, thereby increasing light emission efficiency and reducing reflection of external light.

The low refractive index layer may include particles dispersed in a transparent resin.

The resin may include one or more selected from the group including acryl, polysiloxane, polyurethane, polyurethane acrylate, polyimide, polymethylsilsesquioxane (PMSSQ), and poly(methyl methacrylate) (PMMA).

The particles may be hollow particles. For example, the particles may include one or more selected from the group including silica (SiO₂), magnesium fluoride (MgF₂), and iron oxide (Fe₃O₄). Additionally, the particles may include a shell made of one or more of the aforementioned materials and a hollow space within the shell. In the embodiment, the diameter of the particles may be 10 nm to 200 nm, and the thickness of the shell and the diameter of the hollow space may be determined according to the diameter of the particles.

The particles included in the low refractive index layer may be included in a weight ratio of 10% to 50% with respect to the resin. If the weight ratio of the particles to the resin is 10% or more, the refractive index of the low refractive index layer may be lowered, and if it is 50% or less, it may prevent a decrease in adhesion to adjacent layers. The low refractive index layer may be formed by coating and curing a solution containing a solvent in which the resin and particles are dispersed.

The thickness of the low refractive index layer may be 10 nm to 200 nm. By being formed within the aforementioned thickness range, the low refractive index layer may include a sufficient number of particles to lower the refractive index and improve adhesion to underlying layers.

The refractive index of the low refractive index layer may be lower than the refractive index of the hard coating layer. For example, the refractive index of the low refractive index layer may be less than the refractive index of the hard coating layer by 0.05 or more. When the difference between the refractive index of the low refractive index layer and the refractive index of the hard coating layer is 0.05 or more, by increasing the total reflection of external light at the interface between the low-refractive index layer and the hard coating layer, it is possible to induce destructive interference with light reflected from the surface of the low-refractive index layer. Accordingly, the reflectance of external light in the anti-reflection layer ARL may be reduced. The refractive index of the low refractive index layer may range from 1.3 to 1.43. However, the present disclosure is not limited thereto, and a lower refractive index may be used within a range that is less than the refractive index of the hard coating layer.

The high refractive index layer may include an inorganic material, an organic material, or both an inorganic material and an organic material. Accordingly, the high refractive index layer may be formed of an inorganic layer, an organic layer, or an organic layer containing inorganic particles.

The inorganic material included in the high refractive index layer may be at least one selected from zinc oxide, titanium oxide, zirconium oxide, niobium oxide, tantalum oxide, tin oxide, nickel oxide, silicon oxide, silicon nitride, indium nitride, and gallium nitride.

The organic material included in the high refractive index layer may be at least one selected from poly(3,4-ethylenedioxythiophene) (PEDOT), 4,4’-bis[N-(3-methylphenyl)-N-phenylamino]biphenyl (TPD), 4,4’,4’’-tris[(3-methylphenyl)phenyl aminotriphenylamine (m-MTDATA), 1,3,5-tris[N,N-bis(2-methylphenyl)-amino]-benzene (o-MTDAB), 1,3,5-tris[N,N-bis(3-methylphenyl)-amino]-benzene (m-MTDAB), 1,3,5-tris[N,N-bis(4-methylphenyl)-amino]-benzene (p-MTDAB), 4,4’-bis[N,N-bis(3-methylphenyl)-amino]-diphenylmethane (BPPM), It may be at least one selected from 4,4’-dicarbazolyl-1,1’-biphenyl (CBP), 4,4’,4’’-tris(N-carbazole)triphenylamine (TCTA), 2,2’,2’’-(1,3,5-benzentolyl)tris-[1-phenyl-1H-benzoimidazole] (TPBI), and 3-(4-biphenyl)-4-phenyl-5-t-butylphenyl-1,2,4-triazole (TAZ).

The refractive index of the high refractive index layer may be greater than the refractive index of the low refractive index layer to reduce the reflection of external light. For example, the refractive index of the high refractive index layer may be greater than the refractive index of the low refractive index layer by 0.05 or more. The refractive index of the high refractive index layer may range from 1.53 to 1.7. However, the present disclosure is not limited thereto, and a higher refractive index may be used within a range that is greater than the refractive index of the low refractive index layer.

The thickness of the high refractive index layer may be 50 to 200 nm. By forming the high refractive index layer within the above thickness range, the interface with the low refractive index layer may be formed flat and the bonding strength with the hard coating layer may be prevented from decreasing.

The anti-reflection layer ARL further including the high refractive index layer may further reduce the reflection of external light by significantly increasing the difference in refractive index at the interface with the low refractive index layer.

In some embodiments, the front surface of the window WIN may further include an optical film other than the anti-reflective layer ARL, and may also include an anti-fingerprint layer. However, a polarizing plate is not included because the light blocking layer and color filter layer 220/230 described later reduce the reflectivity of external light and make it difficult for the user to see. Accordingly, in some embodiments, the anti-reflection layer ARL may not be included on the front surface of the window WIN.

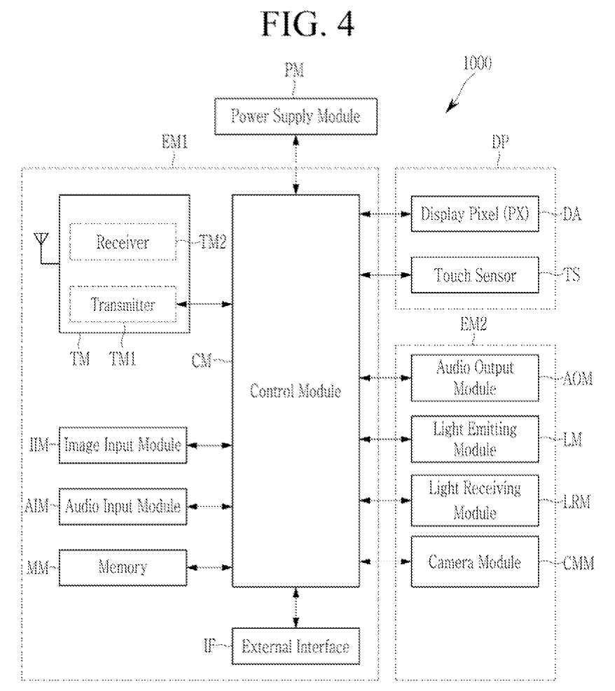

Hereinafter, a display device according to an embodiment will be described through blocks with reference to FIG. 4.

FIG. 4 is a block diagram of a display device according to an embodiment.

Referring to FIG. 4, the display device 1000 may include a display panel DP, a power supply module PM, a first electronic module EM1, and second electronic module EM2. The display panel DP, the power supply module PM, the first electronic module EM1, and the second electronic module EM2 may be electrically connected to each other. FIG. 4 shows the display pixel and the touch sensor TS disposed in the display area DA of the display panel DP as an example.

The power supply module PM may supply power required for overall operation of the display device 1000. The power supply module PM may include a typical battery module.

The first electronic module EM1 and the second electronic module EM2 may include various functional modules for operating the display device 1000. The first electronic module EM1 may be directly mounted on a motherboard electrically connected to the display panel DP, or mounted on a separate substrate to be electrically connected to the motherboard through a connector.

The first electronic module EM1 may include a control module CM, a wireless communication module TM, an image input module IIM, an audio input module AIM, a memory MM, and an external interface IF. Some of the modules are not mounted on the motherboard, but may be electrically connected to the motherboard through the flexible printed circuit board connected thereto.

The control module CM may control the overall operation of the display device 1000. The control module CM may be a microprocessor. For example, the control module CM activates or deactivates the display panel DP. The control module CM may control other modules such as the image input module IIM or the audio input module AIM based on a touch signal received from the display panel DP.

The wireless communication module TM may transmit/receive a wireless signal with another terminal by using a Bluetooth or Wi-Fi line. The wireless communication module TM may transmit/receive a voice signal by using a general communication line. The wireless communication module TM includes a transmitter TM1 that modulates and transmits a signal to be transmitted, and a receiver TM2 that demodulates a received signal.

The image input module IIM may process an image signal to convert it into image data that may be displayed on the display panel DP. The audio input module AIM may receive an external audio signal input by a microphone in a recording mode, a voice recognition mode, and the like to convert it into electrical voice data.

The external interface IF may serve as an interface connected to an external charger, a wired/wireless data port, a card socket (for example, a memory card, a SIM/UIM card), and the like.

The second electronic module EM2 may include an audio output module AOM, a light emitting module LM, a light receiving module LRM, and a camera module CMM, and at least some of them are the optical elements ES and may be disposed on the rear surface of the display panel DP as shown in FIG. 1 and FIG. 2. The optical element ES may include the light emitting module LM, the light receiving module LRM, and the camera module CMM. In addition, the second electronic module EM2 may be directly mounted on the motherboard, mounted on a separate substrate to be electrically connected to the display panel DP through a connector, or electrically connected to the first electronic module EM1.

The audio output module AOM may convert audio data received from the wireless communication module TM or audio data stored in the memory MM to output it to the outside.

The light emitting module LM may generate and output light. The light emitting module LM may output infrared rays. For example, the light emitting module LM may include an LED element. For example, the light receiving module LRM may detect infrared rays. The light receiving module LRM may be activated when infrared rays of a predetermined level or more are sensed. The light receiving module LRM may include a CMOS sensor. After the infrared light generated by the light emitting module LM is output, it may be reflected by an external subject (for example, the user’s finger or face), and then the reflected infrared light may be incident on the light receiving module LRM. The camera module CMM may capture an external image.

In the embodiment, the optical element ES may additionally include a light sensing sensor or a thermal sensing sensor. The optical element ES may sense an external object received through the front surface thereof, or may provide a sound signal such as a voice through the front surface to the outside. In addition, the optical element ES may include a plurality of constituent elements, and is not limited to any one embodiment.

Referring back to FIG. 2, the housing HM may be combined with the cover window WU. The cover window WU may be disposed on the front surface of the housing HM. The housing HM may be combined with the cover window WU to provide a predetermined accommodation space. The display panel DP and the optical element ES may be accommodated in the predetermined accommodation space provided between the housing HM and the cover window WU.

The housing HM may include a material with relatively high rigidity. For example, the housing HM may include a plurality of frames and/or plates made of glass, plastic, or metal, or a combination thereof. The housing HM may stably protect the components of the display device 1000 accommodated in an inner space thereof from external impact.

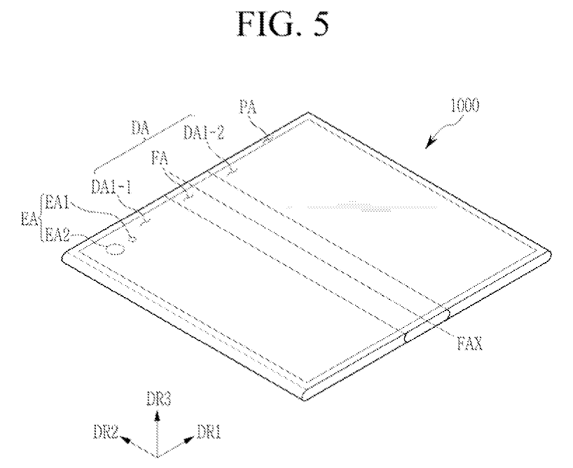

Hereinafter, a structure of a display device 1000 according to some embodiments will be described with reference to FIG. 5.

FIG. 5 is a schematic perspective view of a light emitting display device according to some embodiments.

Descriptions of configurations identical to the aforementioned components may be omitted, and the embodiment of FIG. 5 illustrates a foldable display device having a structure in which the display device 1000 is foldable based on a folding axis FAX.

Referring to FIG. 5, in the embodiment, the display device 1000 may be a foldable display device. The display device 1000 may be folded outwardly or inwardly based on the folding axis FAX. When the display device 1000 is folded outwardly based on the folding axis FAX, display surfaces thereof are each disposed on outer sides in the third direction DR3 so that images may be displayed in both directions. When it is folded inwardly based on the folding axis FAX, the display surface thereof may not be viewed from the outside.

In the embodiment, the display device 1000 may include a display area DA, a component area EA, and a non-display area PA. The display area DA may be divided into a (1-1)-th display area DA1-1, a (1-2)-th display area DA1-2, and a folding area FA. The (1-1)-th display area DA1-1 and the (1-2)-th display area DA1-2 may be disposed on the left and right sides, respectively, with based on (or centered on) a folding axis FAX, and the folding area FA may be disposed between the (1-1)-th display area DA1-1 and the (1-2)-th display area DA1-2. In this case, when folded outwardly based on the folding axis FAX, the (3-1)-th display area DA1-1 and the (1-2)-th display area DA1-2 are disposed on both sides in the third direction DR3, and an image may be displayed in both directions. In addition, when folded inwardly based on the folding axis FAX, the (1-1)-th display area DA1-1 and the (1-2)-th display area DA1-2 may not be viewed from the outside.

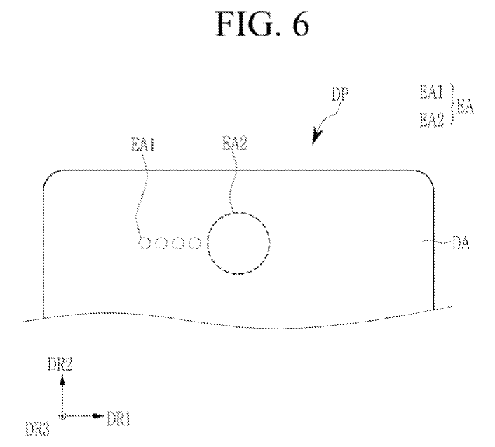

FIG. 6 is an enlarged plan view of a partial area of a light emitting display device according to an embodiment.

FIG. 6 illustrates a portion of the light emitting display panel DP of the light emitting display device according to the embodiment, where the display panel is for a mobile phone.

The light emitting display panel DP has a display area DA disposed on its front surface, and the component area EA is also disposed within the display area DA. Specifically, the component area EA may include a first component area EA1 and a second component area EA2. Additionally, in the embodiment of FIG. 6, the first component area EA1 is disposed to be adjacent to the second component area EA2. In the embodiment of FIG. 6, the first component area EA1 is disposed at the left side of the second component area EA2. The position and number of the first component areas EA1 may vary according to embodiments. In FIG. 6, the second optical element ES2 corresponding to the second component area EA2 may be a camera, and the first optical element ES1 corresponding to the first component area EA1 may be a light sensor.

A plurality of light emitting diodes, and a plurality of pixel circuits that generate and transmit light emitting current to each of the plurality of light emitting diodes are formed in the display area DA. Here, one light emitting diode and one pixel circuit portion are referred to as a pixel PX. One pixel circuit portion and one light emitting diode are formed one-to-one in the display area DA. The display area DA is hereinafter also referred to as a “normal display area.”

Although a structure of the light emitting display panel DP below a cutting line is not shown in FIG. 6, the display area DA may be disposed below the cutting line.

The light emitting display panel DP according to the embodiment may be largely divided into a lower panel layer and an upper panel layer. The lower panel layer is a portion in which the light emitting diode and the pixel circuit portion configuring the pixel are disposed, and may include an encapsulation layer 400 (refer to FIG. 7) covering it. That is, the lower panel layer is from a substrate 100 (refer to FIG. 7) to the encapsulation layer, which also includes an anode, a pixel defining layer 380 (refer to FIG. 7), a light emitting layer EML (refer to FIG. 7), a spacer 385 (refer to FIG. 7), a functional layer FL (refer to FIG. 7), a cathode (refer to FIG. 7), and includes an insulating layer, a semiconductor layer, and a conductive layer between the substrate and the anode. The upper panel layer is a portion disposed at an upper portion of the encapsulation layer, which may include sensing insulating layers 501, 510, and 511 (refer to FIG. 7) capable of sensing a touch and a plurality of sensing electrodes 540 and 541 (refer to FIG. 7), and may include a light blocking layer 220 (refer to FIG. 7), a scattering layer 210 (refer to FIG. 7), a color filter 230 (refer to FIG. 7), and a planarization layer 550 (refer to FIG. 7).

The first component area EA1 may be configured only of transparent layers to allow light to pass through, and a conductive layer or semiconductor layer may not be disposed to allow light to pass through, and the first component area EA1 may have a photosensor area in a lower panel layer, and an opening (hereinafter also referred to as an additional opening) may be formed at a position corresponding to the first component area EA1 in the pixel defining layer, light blocking layer, and color filter layer of the upper panel layer to have a structure that does not block light. Even if the photosensor area is disposed on the lower panel layer, when there is no opening corresponding to the upper panel layer, it may be the display area DA rather than the first component area EA1. One first component area EA1 may include a plurality of adjacent photosensor areas, and in this case, pixels adjacent to the photosensor areas may be included in the first component area EA1. When the first optical element ES1 corresponding to the first component area EA1 uses infrared rays instead of visible light, the first component area EA1 may overlap the light blocking layer 220 that blocks visible light.

The second component area EA2 may include a second component pixel and a light transmission area, and a space between adjacent second component pixels may be the light transmission area.

A scattering layer (refer to 210 in FIG. 7) may be disposed in the first component area EA1 and the second component area EA2, and an opening may be formed in the scattering layer so that at least a portion or all of the scattering layer may be removed.

A peripheral area may be further disposed outside the display area DA. In addition, although FIG. 6 illustrates the display panel for the mobile phone, the present embodiment may be applied as long as it is a display panel in which the optical element may be disposed on the rear surface of the display panel, and it may be a flexible display device. In the case of a foldable display device among flexible display devices, the positions of the second component area EA2 and the first component area EA1 may be formed at positions different from shown those in FIG. 6.

Hereinafter, a structure of a light emitting display panel DP according to an embodiment will be described with reference to FIG. 7.

FIG. 7 is a schematic cross-sectional view of a display panel according to an embodiment.

The light emitting display panel DP according to the embodiment may display an image by forming a light emitting diode on a substrate 110, and may include a plurality of sensing electrodes 540 and 541 to sense a touch, and light emitted from the light emitting diode by including the light blocking layer 220 and color filters 230R, 230G, and 230B has color characteristics of the color filters 230R, 230G, and 230B. In addition, the embodiment of FIG. 7 further includes a scattering layer 210 below the light blocking layer 220, and the scattering layer 210 includes scattering particles 211, such that light may be reflected or refracted by the scattering particles 211. The scattering layer 210 may be a colorless transparent layer having no color in the visible light band. For example, the scattering layer 210 may include a colorless transparent organic material such as an acrylic resin, and in some embodiments, the scattering layer 210 may include a photosensitive transparent organic material. The scattering particles 211 may be formed of a material having a refractive index different from that of the scattering layer 210, and, for example, may include at least one material of titanium dioxide TiO₂, silicon dioxide SiO₂, zirconium oxide Zr₂O₃, aluminum oxide Al₂O₃, hollow silica, acrylate-based materials, and silicon-based materials. Here, the hollow silica may have a structure in which the inside of a particle of silicon dioxide SiO₂, having a three-dimensional shape such as a sphere, has a hollow space.

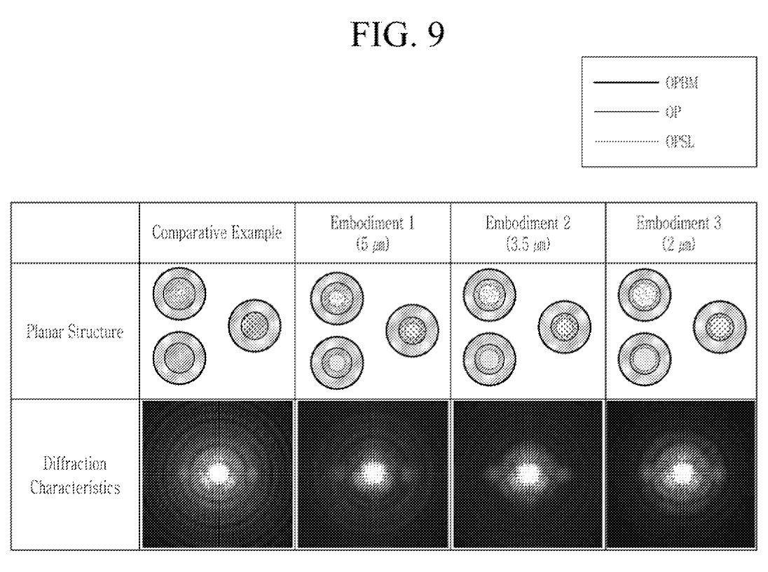

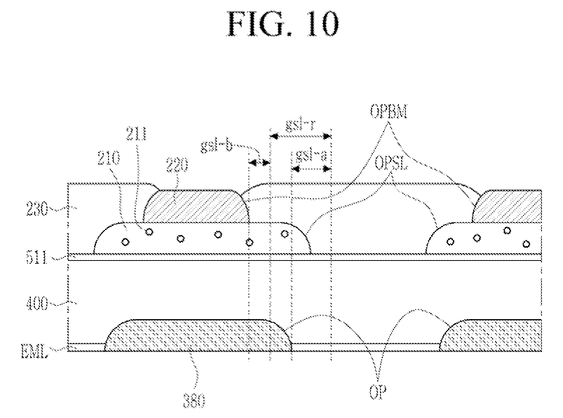

In addition, a polarizing plate is not formed on the front surface of the light emitting display panel DP according to the embodiment, and instead, a pixel defining layer 380 is formed with a black organic material, and a light blocking layer 220 and a color filter 230 are formed on the upper portion so that even if external light is incident on the inside, it is not reflected by an anode or the like and transmitted to the user, and a scattering layer 210 is also disposed on the upper portion so that when external light is incident or reflected, it is scattered and the intensity of the external light may be reduced. In addition, since a polarizing plate is not formed, light emitted from a light emitting layer is not partially absorbed by the polarizing plate so that luminance is not lowered, and thus a light emitting display device having a maximum luminance value of 2500 nits or more may be provided. Specifically, the scattering layer 210 includes the scattering particles 211, which scatter incident light in various directions. In particular, in the case of a light emitting display device that does not include a polarizing plate, when external light is incident, it is reflected and diffracted at the anode (Anode), and various diffraction patterns may occur, but when the external light is scattered through the scattering layer 210, the intensity may be weakened, causing the diffraction pattern to appear weaker. However, light reflected from the anode (Anode) may interfere with the scattering particles 211 of the scattering layer 210, which may cause rainbow mura (refer to the comparative example diffraction characteristics in FIG. 9) to be recognized. Accordingly, in the present disclosure, an opening OPSL (also referred to as a scattering layer opening hereinafter) is formed in the scattering layer 210 corresponding to the anode (Anode), and the position of the scattering layer opening OPSL is adjusted to reduce or eliminate rainbow mura (spots). The position of the scattering layer opening OPSL will be described in detail with reference to FIG. 10 and the like.

The light emitting display panel DP according to the embodiment will now be described in detail with reference to FIG. 7.

The substrate 110 may include a material that has a rigid characteristic such as glass and thus does not bend, or may include a flexible material such as plastic or polyimide that may be bent.

A plurality of thin-film transistors are formed on the substrate 110, and an organic layer 180 covering the thin-film transistors is shown. One pixel includes a light emitting diode and a pixel circuit portion having a plurality of transistors and capacitors formed therein for transmitting light emitting current to the light emitting diode. The pixel circuit portion is not shown in FIG. 7, and the structure of the pixel circuit portion may vary depending on embodiments. In FIG. 7, the organic layer 180 covering the pixel circuit portion is shown.

A light emitting diode including an anode (Anode), a light emitting layer EML, and a cathode (Cathode) is disposed on the organic layer 180.

The anode (Anode) may be formed as a single layer including a transparent conductive oxide layer and a metal material, or a multilayer including them. The transparent conductive oxide layer may include an indium tin oxide (ITO), a poly-ITO, an indium zinc oxide (IZO), an indium gallium zinc oxide (IGZO), and an indium tin zinc oxide (ITZO), and the metal material may include silver (Ag), molybdenum (Mo), copper (Cu), gold (Au), and aluminum (Al).

The light emitting layer EML may be formed of an organic light emitting material, and adjacent light emitting layers EML may display different colors. In some embodiments, each light emitting layer EML may display light of the same color due to the color filters 230R, 230G, and 230B disposed thereon. In some embodiments, the light emitting layer EML may have a structure in which a plurality of light emitting layers are stacked (also referred to as a tandem structure).

A pixel defining layer 380 is disposed on the organic layer 180 and the anode (Anode), the pixel defining layer 380 has an opening OP formed therein, where the opening overlaps (e.g., is above) a portion of the anode (Anode), and the light emitting layer EML is disposed on the anode (Anode) exposed by the opening OP. The light emitting layer EML may be disposed only within the opening OP of the pixel defining layer 380 and is distinguished from adjacent light emitting layers EML by the pixel defining layer 380.

The pixel defining layer 380 may be made of an organic material having a negative type of black color. The organic material having a black color may include a light blocking material, and the light blocking material may include a carbon black, a carbon nanotube, a resin or paste containing black dye, a metal particle such as nickel, aluminum, molybdenum, and an alloy thereof, and a metal oxide particle (for example, chromium nitride). The pixel defining layer 380 may have a black color by including a light blocking material, and may have a characteristic in which light is not reflected and absorbed/blocked. Since a negative type of organic material is used, it may have a characteristic in which portions covered by a mask are removed.

The spacer 385 is formed on the pixel defining layer 380. The spacer 385 includes a first portion 385-1 disposed in a high and narrow area and a second portion 385-2 disposed in a low and wide area. In FIG. 7, the first portion 385-1 and the second portion 385-2 are separated by a dotted line in the spacer 385. Here, the first portion 385-1 may serve to secure rigidity against pressing pressure by enhancing scratch strength. The second portion 385-2 may serve as a contact assistance between the pixel defining layer 380 and the functional layer FL thereon. The first portion 385-1 and the second portion 385-2 are made of the same material, and may be made of a positive type of photosensitive organic material, such as photosensitive polyimide (PSPI). Since it has a positive characteristic, a portion that is not covered by a mask may be removed. The spacer 385 is transparent, so light may be transmitted and/or reflected.

The pixel defining layer 380 may be formed as a negative type, and the spacer 385 may be formed as a positive type, and in some embodiments, they may include the same material.

At least a portion of an upper surface of the pixel defining layer 380 is covered by the spacer 385, and an edge of the second portion 385-2 has a structure spaced apart from an edge of the pixel defining layer 380 such that a portion of the pixel defining layer 380 is not covered by the spacer 385. The second portion 385-2 also covers an upper surface of the pixel defining layer 380 in which the first portion 385-1 is not disposed to enhance an adhesive characteristic between the pixel defining layer 380 and the functional layer FL. In the present embodiment, the spacer 385 is disposed only in an area that overlaps the light blocking layer 220 to be described later in a plan view so that the spacer 385 may not be visible as it is covered by the light blocking layer 220 when viewed from the front of the display panel DP.

A functional layer FL is disposed on the spacer 385 and the exposed pixel defining layer 380, and the functional layer FL may be formed on the entire surface of the light emitting display panel DP or may be formed on the entire area except for a partial area, for example, the light transmission area of the second component area EA2. The functional layer FL may include an electron injection layer, an electron transport layer, a hole transport layer, and a hole injection layer, and the functional layer FL may be disposed above and below the light emitting layer EML. That is, a hole injection layer, a hole transport layer, a light emitting layer EML, an electron transport layer, an electron injection layer, and a cathode (Cathode) may be sequentially disposed on the anode (Anode), so that, among the functional layers FL, the hole injection layer and the hole transport layer may be disposed below the light emitting layer EML, and the electron transport layer and the electron injection layer may be disposed above the light emitting layer EML.

The spacer 385 may enhance the scratch strength on the light emitting display panel DP to reduce the occurrence rate of defects due to pressing pressure, and in some embodiments, it may increase the adhesive strength with the functional layer FL disposed on the upper portion of the spacer 385 to prevent moisture and air from being injected from the outside. In addition, high adhesion has the advantage of eliminating the problem of decreased interlayer adhesion when the light emitting display panel DP, having flexible characteristics, is folded and unfolded.

The cathode (Cathode) may be formed of a light transmission electrode or a reflection electrode. In some embodiments, the cathode may be a transparent or semi-transparent electrode, and may be formed of a metal thin layer that includes lithium (Li), calcium (Ca), lithium fluoride/calcium (LiF/Ca), lithium fluoride/aluminum (LiF/Al), aluminum (Al), silver (Ag), magnesium (Mg), and a compound thereof and has a small work function. In addition, a transparent conductive oxide (TCO) such as indium tin oxide (ITO), indium zinc oxide (IZO), zinc oxide (ZnO), or indium oxide (In2O3) may be further disposed on the metal thin layer. The cathode may be integrally formed on the entire surface of the light emitting display panel DP.

An encapsulation layer 400 is disposed on the cathode (Cathode). The encapsulation layer 400 includes at least one inorganic layer and at least one organic layer, and in FIG. 7, the encapsulation layer 400 has a triple-layer structure including a first inorganic encapsulation layer 401, an organic encapsulation layer 402, and a second inorganic encapsulation layer 403. The encapsulation layer 400 may be for protecting the light emitting layer EML made of an organic material from moisture or oxygen that may be introduced from the outside. In some embodiments, the encapsulation layer 400 may have a structure in which an inorganic layer and an organic layer are sequentially further stacked.

Sensing insulating layers 501, 510, and 511 and a plurality of sensing electrodes 540 and 541 are disposed on the encapsulation layer 400 for touch sensing. In the embodiment of FIG. 7, a touch is sensed in a capacitive type by using two sensing electrodes 540 and 541, but in the embodiments, a touch may be sensed in a self-cap method by using only one sensing electrode. The plurality of sensing electrodes 540 and 541 may be insulated with a second sensing insulating layer 510 therebetween, and a lower sensing electrode 541 is disposed on a first sensing insulating layer 501, and an upper sensing electrode 540 is disposed on the second sensing insulating layer 510, and the upper sensing electrode 540 is covered by a third sensing insulating layer 511. The plurality of sensing electrodes 540 and 541 may be electrically connected through an opening disposed in the second sensing insulating layer 510. Here, the sensing electrodes 540 and 541 may include a metal such as aluminum (Al), copper (Cu), silver (Ag), gold (Au), molybdenum (Mo), titanium (Ti), or tantalum (Ta), or a metal alloy thereof, and may be formed as a single layer or a multilayer.

A scattering layer 210, a light blocking layer 220, and color filters 230R, 230G, and 230B are sequentially disposed on the third sensing insulating layer 511.

The light blocking layer 220 may be disposed to overlap the sensing electrodes 540 and 541 in a plan view, and may be disposed so as to not overlap the anode (Anode) in a plan view. This is to prevent the anodes (Anode) and the light emitting layer EML capable of displaying an image from being covered by the light blocking layer 220 and the sensing electrodes 540 and 541.

The scattering layer 210 may be disposed to overlap the light blocking layer 220 and the sensing electrodes 540 and 541 in a plan view, and a portion of the scattering layer 210 may overlap the anode (Anode) in a plan view, and another portion thereof may not overlap the anode (Anode). At least a portion of the scattering layer 210 may also overlap the pixel defining layer 380 in a plan view. The scattering layer 210 includes scattering particles 211 capable of scattering light, and has an opening OPSL (also referred to as a scattering layer opening hereinafter) that overlaps (e.g., is directly above) at least a portion of the opening OP of the pixel defining layer 380 in a plan view. The size, shape, and arrangement direction of the opening OPSL of the scattering layer 210 may vary, and may have various planar shapes such as circular or elliptical.

Referring to FIG. 7, the light blocking layer 220 is disposed only in an area that overlaps (e.g., is directly above) the pixel defining layer 380 in a plan view, and one side of the light blocking layer 220 is disposed inwardly from a corresponding side of the pixel defining layer 380.

The light blocking layer 220 also has a second opening OPBM (hereinafter also referred to as a second opening), and the area (e.g., diameter in plan view) of the second opening OPBM of the light blocking layer 220 is formed larger than the opening OP of the pixel defining layer 380, and the opening OP of the pixel defining layer 380 may be disposed within the second opening OPBM of the light blocking layer 220 in a plan view. The second opening OPBM of the light blocking layer 220 may be formed larger than (e.g., having a larger diameter/width in plan view) the opening OPSL of the scattering layer 210, and at least a portion of the second opening OPBM of the light blocking layer 220 may overlap the opening OPSL of the scattering layer 210 in a plan view.

In addition, one side of the spacer 385 is disposed inwardly by a predetermined gap g-1 from a corresponding side of the pixel defining layer 380, and the spacer 385 is disposed inwardly with respect to one side of the light blocking layer 220. As a result, when viewed from the front of the display panel DP, the spacer 385 may not be visible because it is covered by the light blocking layer 220.

When external light is incident, it may pass through the second opening OPBM of the light blocking layer 220 and the opening OPSL of the scattering layer 210, and may then be reflected by the sidewall of the opening OP of the pixel defining layer 380. The sidewall of the opening OP of the pixel defining layer 380 is curved so that color separation occurs depending on the reflected position, and the reflected light may appear as a rainbow mura. Such color-separated reflected light may be easily seen by the user, which may degrade display quality, but in the present embodiment, due to the scattering particles 211 disposed in the scattering layer 210, light is scattered, which may make it difficult for the user to easily recognize the reflected light. Particularly, as will be described later, rainbow mura may be reduced or eliminated by adjusting the position of the opening OPSL of the scattering layer 210 or the position of the edge of the opening OPSL of the scattering layer 210. In addition, the shape, size, and angle of the opening OPSL of the scattering layer 210 may be varied, and a single panel may include various openings OPSL of the scattering layer 210. As a result, the degradation of display quality due to reflected light may be reduced by preventing the user from perceiving external light as rainbow mura. This will be described in more detail through various embodiments in FIG. 8 and below.

In FIG. 7, the opening OP of the pixel defining layer 380 is illustrated as being larger than the opening OPSL of the scattering layer 210, and the second opening OPBM of the light blocking layer 220 is illustrated as being larger than the opening OPSL of the scattering layer 210 and the opening OP of the pixel defining layer 380. However, the width relationship of these openings may vary depending on the embodiment, the shape, size, arrangement, and cross-section of each opening.

Color filters 230R, 230G, and 230B are disposed on the sensing insulating layers 501, 510, and 511, the scattering layer 210, and the light blocking layer 220. The color filters 230R, 230G, and 230B include a red color filter 230R that transmits red light, a green color filter 230G that transmits green light, and a blue color filter 230B that transmits blue light. Each of the color filters 230R, 230G, and 230B may be disposed to overlap the anode (Anode) of the light emitting diode in a plan view. Since light emitted from the light emitting layer EML may be emitted while changing to the corresponding color as it passes through the color filter, all light emitted from the light emitting layer EML may have the same color. However, light of different colors is displayed in the light emitting layer EML, and the displayed color may be enhanced by passing through a color filter of the same color.

The light blocking layer 220 may be disposed between each of the color filters 230R, 230G, and 230B. In some embodiments, the color filters 230R, 230G, and 230B may be replaced with a color conversion layer, or may further include a color conversion layer. The color conversion layer may include a quantum dot.

The planarization layer 550 covering the color filters 230R, 230G, and 230B is disposed on the color filters 230R, 230G, and 230B. The planarization layer 550 is for planarizing the upper surface of the light emitting display panel, and may be a transparent organic insulating layer including one or more materials selected from the group including polyimide, polyamide, an acrylic resin, benzocyclobutene, and a phenol resin.

In some embodiments, a low refractive layer and an additional planarization layer may be further may be further disposed on the planarization layer 550 in order to improve frontal visibility and light emitting efficiency of the display panel. Light may be emitted while being refracted to the front side by the low refractive layer and the additional planarization layer having a high refractive characteristic. In this case, in some embodiments, the low refractive layer and the additional planarization layer may be directly disposed on the color filter 230 while the planarization layer 550 is omitted.

In the present embodiment, no polarizing plate is formed on the planarization layer 550. That is, the polarizing plate may serve to prevent the display quality from being degraded while being recognized by the user due to external light being reflected from the anode or the sidewall of the opening OP of the pixel defining layer 380. However, the polarizing plate not only reduces the reflection of external light, but also reduces the light emitted from the light emitting layer EML, so there is a disadvantage in that more power is consumed to display a certain brightness. In order to reduce power consumption, the light emitting display device of the present embodiment may not include a polarizing plate. In addition, since the light emitting display device of the present embodiment does not form a polarizing plate, the brightness does not decrease as light emitted from the light emitting layer is partially absorbed by the polarizing plate so that a light emitting display device having a maximum brightness value of 2500 nits or more may be provided.

In addition, in the present embodiment, the scattering layer 210 is formed under the light blocking layer 220, and the edge of the opening OPSL of the scattering layer 210 is formed to be disposed within a certain range so that external light is not reflected and is not recognized as a rainbow mura, thereby preventing degradation in display quality. Therefore, there is no need to form a polarizing plate separately on the front surface of the light emitting display panel DP.

In the embodiment of FIG. 7, the scattering layer 210 is disposed between the third sensing insulating layer 511 and the light blocking layer 220, and is formed in a structure that protrudes toward the front surface (the third direction DR3) of the light emitting display panel DP based on the third sensing insulating layer 511. The scattering layer 210 may have a tapered side surface, and the taper angle may be greater than 0 degrees and less than 90 degrees toward the third direction DR3 from the first direction DR1 or the second direction DR2. Compared to a comparative example in which the scattering layer 210 has a structure protruding toward the rear surface (in the opposite direction to the third direction DR3), the embodiment in which the scattering layer 210 has a structure protruding toward the front surface is not only easy to manufacture using a photolithography-type exposure and development process, but also easy to control the taper angle so that the rainbow mura described later may be effectively reduced.

Hereinafter, first, through the structure of the light emitting display panel DP formed in the display area DA with reference to FIG. 8, an embodiment will be described in which the openings OPr, OPg, and OPb of the pixel defining layer 380, the second openings OPBMr, OPBMg, and OPBMb of the light blocking layer 220, and the openings OPSLr, OPSLg, and OPSLb of the scattering layer 210 are formed in a circle having the same center, and the openings OPSLr, OPSLg, and OPSLb of the scattering layer 210, the openings OPr, OPg, and OPb of the pixel defining layer 380, and the second openings OPBMr, OPBMg, and OPBMb of the light blocking layer 220 are largely formed in that order.

FIG. 8 is a plan view of a portion of a display panel according to an embodiment.

In FIG. 8, only the openings OPr, OPg, and OPb of the pixel defining layer 380 corresponding respectively to the three red, green, and blue subpixels belonging to one unit pixel, the second openings OPBMr, OPBMg, and OPBMb of one light blocking layer 220 corresponding thereto, and the openings OPSLr, OPSLg, and OPSLb of one scattering layer 210 are shown. Here, r, g, and b may correspond to red, green, and blue, respectively.

In FIG. 8, the red opening OPr, the green opening OPg, and the blue opening OPb of the pixel defining layer 380, and the red second opening OPBMr, the green second opening OPBMg, and the blue second opening OPBMb of the light blocking layer 220 may be formed in a circular shape having different radii according to the size of the corresponding openings OPSLr, OPSLg, OPSLb of the scattering layer 210. Each of the openings OPr, OPg, and OPb and the second openings OPBMr, OPBMg, and OPBMb of the same color may have the same radius and be formed in the same size, or may be formed in two or more different sizes.

The openings OPr, OPg, and OPb of one pixel defining layer 380 correspond to the openings OPSLr, OPSLg, and OPSLb of one scattering layer 210 and the second openings OPBMr, OPBMg, and OPBMb of one light blocking layer 220. That is, within the second openings OPBMr, OPBMg, and OPBMb of the light blocking layer 220, the openings OPSLr, OPSLg, and OPSLb of the scattering layer 210 and the openings OPr, OPg, and OPb of the pixel defining layer 380 respectively corresponding to the second openings OPBMr, OPBMg, and OPBMb of the light blocking layer 220 are disposed. The second openings OPBMr, OPBMg, and OPBMb of the corresponding light blocking layers 220, the openings OPSLr, OPSLg, and OPSLb of the scattering layer 210, and the openings OPr, OPg, and OPb of the pixel defining layer 380 may overlap each other in a plan view.

In FIG. 8, the pixel defining layer 380 is disposed at an outer portion of the openings OPr, OPg, and OPb, the scattering layer 210 is disposed at an outer portion of the openings OPSLr, OPSLg, and OPSLb of the scattering layer 210, and the light blocking layer 220 is also disposed at an outer portion of the second openings OPBMr, OPBMg, and OPBMb. In FIG. 8, hatching is additionally drawn to indicate a portion of the scattering layer 210 that is not obscured by the light blocking layer 220 and is visible from the front. This hatching may indicate, throughout the specification, the scattering layer 210 that is not covered by the light blocking layer 220, thereby indicating a portion in which light may be scattered by the scattering particles (refer to 211 in FIG. 7). In addition, in FIG. 8, three different types of hatching are used to indicate red-light, green-light, and blue-light emitting layers that may be exposed by the openings OPr, OPg, and OPb of the pixel defining layer 380, respectively. In the embodiment of FIG. 8, it may be seen that some of the light emitting layers exposed by the openings OPr, OPg, and OPb of the pixel defining layer 380 overlap the scattering layer 210, and the remainder do not overlap the scattering layer 210.

In the embodiment of FIG. 8, the openings OPr, OPg, and OPb of the pixel defining layer 380 and the second openings OPBMr, OPBMg, and OPBMb of the light blocking layer 220 are formed to have a circular planar shape, and the openings OPSLr, OPSLg, and OPSLb of the scattering layer 210 are also formed to have a circular planar shape, and the three openings may share the same center.

In the embodiment of FIG. 8, a radius value of the circular shape of the openings OPr, OPg, and OPb of the pixel defining layer 380 may be larger than a radius value of the elliptical shape of the openings OPSLr, OPSLg, and OPSLb of the scattering layer 210, and a radius value of the circular shape of the second openings OPBMr, OPBMg, and OPBMb of the light blocking layer 220 is also formed to be larger than the radius value of the openings OPSLr, OPSLg, and OPSLb of the scattering layer 210 and the radius value of the openings OPr, OPg, and OPb of the pixel defining layer 380. In some embodiments, the radius value of the openings OPSLr, OPSLg, and OPSLb of the scattering layer 210 may be larger than the radius value of the openings OPr, OPg, and OPb of the pixel defining layer 380 so that the openings OPr, OPg, and OPb of the pixel defining layer 380 may not be covered by the scattering layer 210. In some embodiments, the openings OPSLr, OPSLg, and OPSLb of the scattering layer 210 may be smaller by 1 µm or more than the second openings OPBMr, OPBMg, and OPBMb of the light blocking layer 220, and may be smaller by 10 µm or less than the openings OPr, OPg, and OPb of the pixel defining layer 380. The range within which the edges of the openings OPSLr, OPSLg, and OPSLb of the scattering layer 210 capable of removing rainbow mura may be disposed will be described in more detail with reference to FIG. 10.

In the embodiment of FIG. 8, the openings OPSLr, OPSLg, and OPSLb of the scattering layer 210 are formed for sub-pixels of all colors, but in some embodiments, the openings OPSLr, OPSLg, and OPSLb of the scattering layer 210 may not be formed for one or two colors, and a light emitting layer of the corresponding color may have a structure covered by the scattering layer 210. The arrangement of the openings OPSLr, OPSLg, and OPSLb of the scattering layer 210 may be periodic or random. Further, a thickness or a haze value of the scattering layer 210 may be the same for all colors, and in some embodiments, may be formed to have different thicknesses and haze values depending on the color.

The reflection characteristics of the embodiment in which the openings OPr, OPg, and OPb of the pixel defining layer 380, the openings OPSLr, OPSLg, and OPSLb of the scattering layer 210, and the second openings OPBMr, OPBMg, and OPBMb of the light blocking layer 220 are formed in a circular shape as described above will be described with reference to FIG. 9.

FIG. 9 is a table comparing characteristics of a comparative example and three example embodiments.

FIG. 9 shows diffraction characteristics of three embodiments in which the overlapping interval between the openings OPr, OPg, and OPb of the pixel defining layer 380 and the openings OPSLr, OPSLg, and OPSLb of the scattering layer 210 in the comparative example and the embodiment of FIG. 8 is changed. Specifically, in the comparative example, the scattering layer 210 does not have an opening, and thus the openings OPr, OPg, and OPb of the pixel defining layer 380 are covered by the scattering layer. In the embodiments, the scattering layer 210 has the openings OPSLr, OPSLg, and OPSLb, and the overlapping interval between the openings OPr, OPg, and OPb of the pixel defining layer 380 and the openings OPSLr, OPSLg, and OPSLb of the scattering layer 210, respectively, is the largest in Embodiment 1 and the narrowest in Embodiment 3. That is, an overlapping interval may refer to an amount (e.g., a measured width) of overlapping between an opening OPSL in the scattering layer 210 and an opening OP in the pixel defining layer. For example, in Embodiment 1, the difference between the diameter of opening OPSL and the diameter of opening OP is greatest amongst the embodiments shown in FIG. 9, and this difference, 5 µm, corresponds to the overlapping interval. In Embodiment 3, the difference between the diameter of opening OPSL and the diameter of opening OP is least amongst the embodiments shown in FIG. 9, and this difference, 2 µm, corresponds to the overlapping interval.

More specifically, in Embodiment 1, the overlapping interval between the openings OPr, OPg, and OPb of the pixel defining layer 380 and the openings OPSLr, OPSLg, and OPSLb of the scattering layer 210 is 5 µm, in Embodiment 2, the overlapping interval between the openings OPr, OPg, and OPb of the pixel defining layer 380 and the openings OPSLr, OPSLg, and OPSLb of the scattering layer 210 is 3.5 µm, and in Embodiment 3, the overlapping interval between the openings OPr, OPg, and OPb of the pixel defining layer 380 and the openings OPSLr, OPSLg, and OPSLb of the scattering layer 210 is 2 µm.

Referring to FIG. 9, it may be confirmed that strong rainbow mura is observed in the diffraction characteristics of the comparative example. In contrast, in Embodiment 1 to Embodiment 3, it may be confirmed that rainbow mura is reduced. Specifically, in the embodiments of FIG. 9, rainbow mura is less discernible in Embodiment 2 compared to Embodiment 1, and the rainbow mura is weaker in Embodiment 2 compared to Embodiment 3.

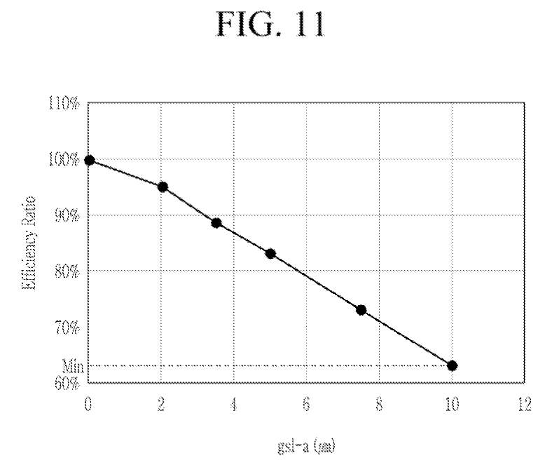

With reference to FIG. 9, the position of the edge of the openings OPSLr, OPSLg, and OPSLb of the scattering layer 210, which allows for easier reduction of rainbow mura compared to the comparative example, will be described through FIG. 10 and FIG. 11.

FIG. 10 is a diagram illustrating an edge position of a scattering layer opening in an embodiment, and FIG. 11 is a graph showing a relationship between an edge of a scattering layer opening and luminous efficiency.

First, the embodiment of FIG. 10 will be described.

FIG. 10 is an enlarged view of only a portion of the cross-sectional structure of FIG. 7, and compared to FIG. 7, some layers are omitted.

FIG. 10 illustrates a range gsl-r (hereinafter also referred to as “edge position range”) in which the edges of the openings OPSLr, OPSLg, and OPSLb of the scattering layer 210 may be disposed. Here, the edge position range gsl-r of the openings OPSLr, OPSLg, and OPSLb of the scattering layer 210 is defined by a maximum edge position gsl-b at which the openings OPSLr, OPSLg, and OPSLb of the scattering layer 210 may be formed the largest, and a minimum edge position gsl-a at which the openings OPSLr, OPSLg, and OPSLb of the scattering layer 210 may be formed the smallest.

Specifically, the maximum edge position range gsl-b is a position at a horizontal distance of 1 μm inward from the edge of the second openings OPBMr, OPBMg, and OPBMb of the light blocking layer 220, and the minimum edge position range gsl-a is a position at a horizontal distance of 10 μm inward from the edge of the openings OPr, OPg, and OPb of the pixel defining layer 380. Therefore, the openings OPSLr, OPSLg, and OPSLb of the scattering layer 210 may be smaller by 1 µm or more than the second openings OPBMr, OPBMg, and OPBMb of the light blocking layer 220, and may be smaller by 10 µm or less than the openings OPr, OPg, and OPb of the pixel defining layer 380.

If the edge of the opening OPSLr, OPSLg, or OPSLb of the scattering layer 210 is too close to the second opening OPBMr, OPBMg, or OPBMb of the light blocking layer 220, the external light incident on the scattering layer 210 is insufficient to improve the rainbow mura, and if the scattering layer 210 covers too much of the opening OPr, OPg, or OPb of the pixel defining layer 380, not only is the light efficiency lowered as shown in FIG. 11, but rainbow mura occurs similar to the comparative example.

FIG. 11 shows a graph of the efficiency ratio for the minimum edge position range gsl-a, where the efficiency ratio means the ratio of the total light emitted from the light emitting layer.

Referring to FIG. 11, it may be confirmed that as the minimum edge position range gsl-a increases and the degree to which the scattering layer 210 covers the openings OPr, OPg, and OPb of the pixel defining layer 380 increases, the efficiency ratio gradually decreases. Here, considering power consumption and a minimum efficiency ratio Min required in the light emitting display device, it may be confirmed that the minimum edge position range gsl-a according to the embodiment is 10 μm. Here, the haze value of the scattering layer 210 is 40%, and the minimum efficiency ratio Min may be about 63%. The minimum efficiency ratio Min value is a value set to have an efficiency value equivalent to that when a polarizing plate is attached, and is a value to have improved efficiency compared to the comparative example in which a polarizing plate is attached.

Therefore, when the edge of the opening OPSLr, OPSLg, or OPSLb of the scattering layer 210 is disposed within the edge position range gsl-r, even if external light is reflected, rainbow mura is weakly visible or does not occur, and additionally, various characteristics of the light emitting display device, such as efficiency ratio and power consumption, may be satisfied.

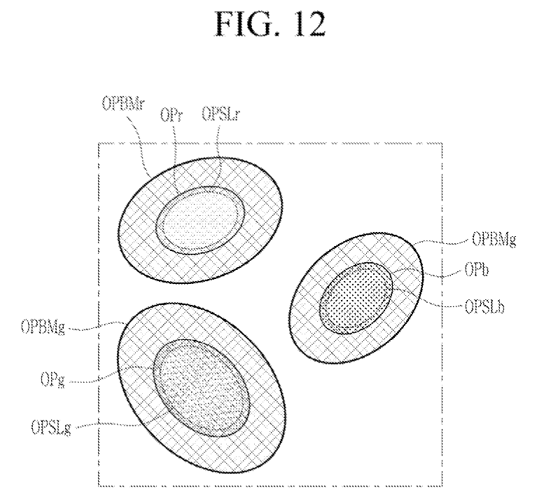

In the above, the openings OPr, OPg, and OPb of the pixel defining layer 380, the openings OPSLr, OPSLg, and OPSLb of the scattering layer 210, and the second openings OPBMr, OPBMg, and OPBMb of the light blocking layer 220 have been described with a focus on an example in which they are formed in a circular shape. However, in some embodiments, their planar shapes may have other shapes besides circular ones, and below, an embodiment in which the openings OPr, OPg, and OPb of the pixel defining layer 380, the openings OPSLr, OPSLg, and OPSLb of the scattering layer 210, and the second openings OPBMr, OPBMg, and OPBMb of the light blocking layer 220 are formed in an elliptical shape will be described with reference to FIG. 12.

FIG. 12 is a plan view of a portion of a display panel according to some embodiments.

In FIG. 12, unlike FIG. 8, the openings OPr, OPg, and OPb of the pixel defining layer 380, the second openings OPBMr, OPBMg, and OPBMb of the light blocking layer 220, and the openings OPSLr, OPSLg, and OPSLb of the scattering layer 210 are all formed in an elliptical shape, and this is an embodiment in which the openings OPSLr, OPSLg, and OPSLb of the scattering layer 210, the openings OPr, OPg, and OPb of the pixel defining layer 380, and the second openings OPBMr, OPBMg, and OPBMb of the light blocking layer 220 are formed largely in that order.

In FIG. 12, only the openings OPr, OPg, and OPb of the pixel defining layer 380 corresponding to each of the three red, green, and blue sub-pixels belonging to one unit pixel, the corresponding second openings OPBMr, OPBMg, and OPBMb of one light blocking layer 220, and the openings OPSLr, OPSLg, and OPSLb of one scattering layer 210 are shown. Here, r, g, and b may correspond to red, green, and blue, respectively.

In FIG. 12, the red opening OPr, the green opening OPg, and the blue opening OPb of the pixel defining layer 380, and the red second opening OPBMr, the green second opening OPBMg, and the blue second opening OPBMb of the light blocking layer 220 may be formed in an elliptical shape having different sizes according to the size of the corresponding openings OPSLr, OPSLg, OPSLb of the scattering layer 210. Additionally, the major axis directions of the openings OPr, OPg, and OPb of the pixel defining layer 380, the second openings OPBMr, OPBMg, and OPBMb of the light blocking layer 220, and the openings OPSLr, OPSLg, and OPSLb of the scattering layer 210, which overlap each other, may each be the same. Each of the openings OPr, OPg, and OPb and the second openings OPBMr, OPBMg, and OPBMb of the same color may have the same major and minor axis lengths to be formed to have the same size, or may be formed to have two or more different sizes.

In FIG. 12, the pixel defining layer 380 is disposed at an outer portion of the openings OPr, OPg, and OPb, the scattering layer 210 is disposed at an outer portion of the openings OPSLr, OPSLg, and OPSLb of the scattering layer 210, and the light blocking layer 220 is also disposed at an outer portion of the second openings OPBMr, OPBMg, and OPBMb. In FIG. 12, hatching is additionally drawn to indicate a portion of the scattering layer 210 that is not obscured by the light blocking layer 220 and is visible from the front. This hatching may indicate, throughout the specification, the scattering layer 210 that is not covered by the light blocking layer 220, thereby indicating a portion in which light may be scattered by the scattering particles (refer to 211 in FIG. 7). In addition, in FIG. 12, three different types of hatching are used to indicate red-, green-, and blue-light emitting layers that may be exposed by the openings OPr, OPg, and OPb of the pixel defining layer 380, respectively. In the embodiment of FIG. 12, it may be seen that the light emitting layer exposed by the openings OPr, OPg, and OPb of the pixel defining layer 380 does not overlap the scattering layer 210.

In the embodiment of FIG. 12, the openings OPr, OPg, and OPb of the pixel defining layer 380 and the second openings OPBMr, OPBMg, and OPBMb of the light blocking layer 220 are formed to have an elliptical planar shape, and the openings OPSLr, OPSLg, and OPSLb of the scattering layer 210 are also formed to have an elliptical planar shape, and the major axis directions of the elliptical shapes of the three openings may be the same.

In the embodiment of FIG. 12, the openings OPr, OPg, and OPb of the pixel defining layer 380 may be larger than the openings OPSLr, OPSLg, and OPSLb of the scattering layer 210, and the second openings OPBMr, OPBMg, and OPBMb of the light blocking layer 220 are also formed larger than the openings OPSLr, OPSLg, and OPSLb of the scattering layer 210 and the openings OPr, OPg, and OPb of the pixel defining layer 380. In some embodiments, the openings OPSLr, OPSLg, and OPSLb of the scattering layer 210 may be larger than the openings OPr, OPg, and OPb of the pixel defining layer 380 so that the openings OPr, OPg, and OPb of the pixel defining layer 380 may not be covered by the scattering layer 210.

In the embodiment of FIG. 12, as in FIG. 10, the openings OPSLr, OPSLg, and OPSLb of the scattering layer 210 may be smaller by 1 µm or more than the second openings OPBMr, OPBMg, and OPBMb of the light blocking layer 220, and may be smaller by 10 µm or less than the openings OPr, OPg, and OPb of the pixel defining layer 380.

In some embodiments, the major axis directions of the openings OPr, OPg, and OPb of the pixel defining layer 380, the openings OPSLr, OPSLg, and OPSLb of the scattering layer 210, and/or the second openings OPBMr, OPBMg, and OPBMb of the light blocking layer 220 may be aligned at various angles or formed in elliptical shapes with various eccentricities. Each of the openings corresponding to the same color may be formed with the same eccentricity or may be formed with two or more different eccentricities.

In some embodiments, at least one of the openings OPr, OPg, and OPb of the pixel defining layer 380, the openings OPSLr, OPSLg, and OPSLb of the scattering layer 210, and/or the second openings OPBMr, OPBMg, and OPBMb of the light blocking layer 220 may have an elliptical shape, while another may have a circular shape so that openings of different planar shapes may be formed to overlap each other.

In the embodiment of FIG. 12, the openings OPSLr, OPSLg, and OPSLb of the scattering layer 210 are formed for sub-pixels of all colors, but in some embodiments, the openings OPSLr, OPSLg, and OPSLb of the scattering layer 210 may not be formed for one or two colors, and a light emitting layer of the corresponding color may have a structure covered by the scattering layer 210. The arrangement of the openings OPSLr, OPSLg, and OPSLb of the scattering layer 210 may be periodic or random. Further, a thickness or a haze value of the scattering layer 210 may be the same for all colors, and in some embodiments, may be formed to have different thicknesses and haze values depending on the color.

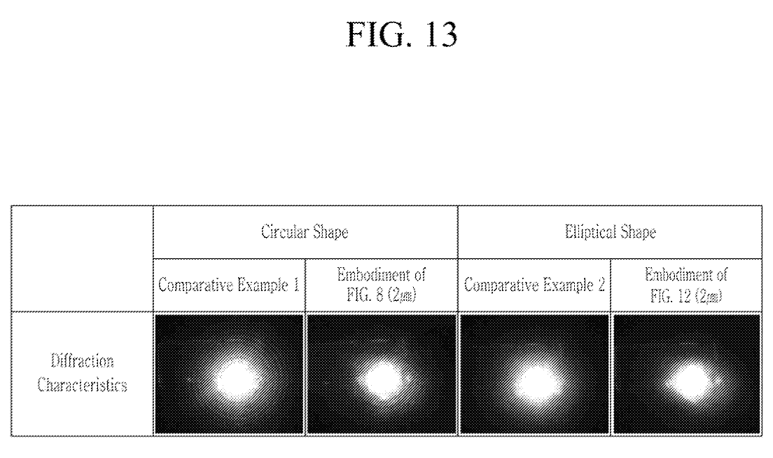

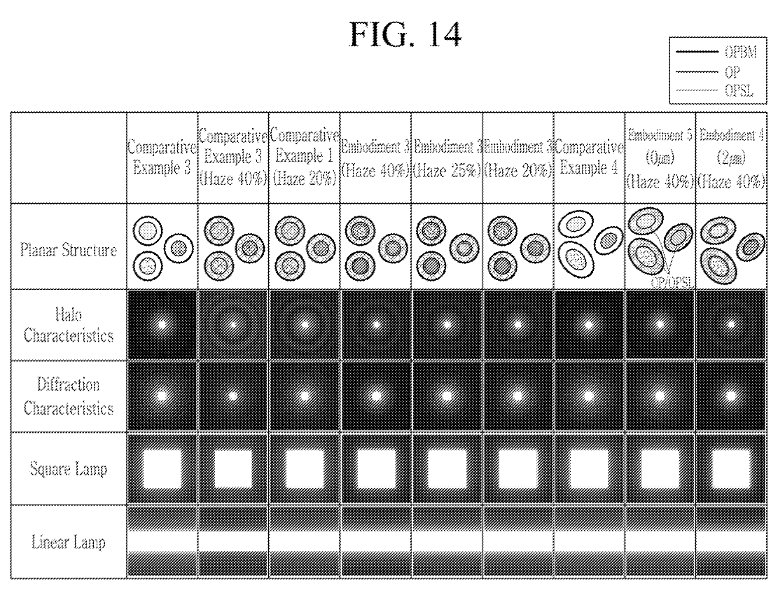

Hereinafter, diffraction characteristics for comparative examples and various examples will be described with reference to FIG. 13 and FIG. 14.

FIG. 13 and FIG. 14 are tables comparing characteristics of comparative examples and example embodiments.

First, FIG. 13 shows diffraction characteristics for two comparative examples and two example embodiments.

In Comparative Example 1 in FIG. 13, as in the comparative example of FIG. 9, the openings OPr, OPg, and OPb of the pixel defining layer 380 and the second openings OPBMr, OPBMg, and OPBMb of the light blocking layer 220 are formed in a circular shape, and since the scattering layer 210 does not have an opening, the openings OPr, OPg, and OPb of the pixel defining layer 380 are covered with the scattering layer. The embodiment of FIG. 8 (2 μm) in FIG. 13 is an embodiment in which, like Embodiment 3 of FIG. 9, the openings OPr, OPg, and OPb of the pixel defining layer 380, the openings OPSLr, OPSLg, and OPSLb of the scattering layer 210, and the second openings OPBMr, OPBMg, and OPBMb of the light blocking layer 220 are formed in a circular shape, and the overlapping interval between the openings OPr, OPg, and OPb of the pixel defining layer 380 and the openings OPSLr, OPSLg, and OPSLb of the scattering layer 210 is 2 μm.

In FIG. 13, Comparative Example 2 has the openings OPr, OPg, and OPb of the pixel defining layer 380 and the second openings OPBMr, OPBMg, and OPBMb of the light blocking layer 220 formed in an elliptical shape, and since the scattering layer 210 does not have an opening, the openings OPr, OPg, and OPb of the pixel defining layer 380 are covered with the scattering layer. The embodiment of FIG. 12 (2 μm) in FIG. 13 is an embodiment in which, like the embodiment of FIG. 12, the openings OPr, OPg, and OPb of the pixel defining layer 380, the openings OPSLr, OPSLg, and OPSLb of the scattering layer 210, and the second openings OPBMr, OPBMg, and OPBMb of the light blocking layer 220 are all formed in an elliptical shape, and the overlapping interval between the openings OPr, OPg, and OPb of the pixel defining layer 380 and the openings OPSLr, OPSLg, and OPSLb of the scattering layer 210 is 2 μm.

When comparing the diffraction characteristics of FIG. 13, it may be confirmed that the rainbow mura is most strongly visible in the case of Comparative Example 1, and it may be confirmed that the rainbow mura is weakly visible in the example of FIG. 8 (2 μm) compared to Comparative Example 1. Particularly, referring to Embodiment 1 and Embodiment 2 of FIG. 9, by changing the overlapping interval between the openings OPr, OPg, and OPb of the pixel defining layer 380 and the openings OPSLr, OPSLg, and OPSLb of the scattering layer 210, the rainbow mura may be made to appear weaker.

Based on FIG. 13, the diffraction characteristics of Comparative Example 2 in which the opening is formed in an elliptical shape and the embodiment of FIG. 12 (2 μm) are as follows.

It may be confirmed that Comparative Example 2 shows fainter rainbow mura compared to Comparative Example 1. This is because the rainbow mura, which appears circular, is reduced due to the major axis direction of the elliptical shape. Furthermore, if the major axis direction of the elliptical shape is varied, the rainbow mura may be further reduced.

The diffraction characteristics of the embodiment of FIG. 12 (2 μm) show that rainbow mura is removed more effectively than in Comparative Example 2, confirming the effect of reduced rainbow mura due to the formation of the openings OPSLr, OPSLg, and OPSLb of the scattering layer 210. In the embodiment of FIG. 12 (2 μm), the overlapping interval between the openings OPr, OPg, and OPb of the pixel defining layer 380 and the openings OPSLr, OPSLg, and OPSLb of the scattering layer 210 is 2 μm, but the effect of reduced rainbow mura may be adjusted by changing the overlapping interval, and as shown in FIG. 10, the edge of the opening OPSLr, OPSLg, or OPSLb of the scattering layer 210 may be formed within a range that is 1 μm or more smaller than the second opening OPBMr, OPBMg, or OPBMb of the light blocking layer 220 and 10 μm or less smaller than the opening OPr, OPg, or OPb of the pixel defining layer 380.

Hereinafter, diffraction characteristics will be described with reference to FIG. 14.

FIG. 14 illustrates the diffraction characteristics of four comparative examples (Comparative Example 1 (Haze 40%), Comparative Example 1 (Haze 20%), Comparative Example 3, Comparative Example 4 and five embodiments (Embodiment 3 (Haze 40%), Embodiment 3 (Haze 25%), Embodiment 3 (Haze 20%), Embodiment 4 (2 μm, Haze 40%), Embodiment 5 (0 μm, Haze 40%)).

Comparative Example 1 is identical to Comparative Example 1 of FIG. 13, and unlike FIG. 13, it shows a comparison of diffraction characteristics while changing the haze value of the scattering layer. Comparative Example 3 is different from Comparative Example 1 in that the openings OPr, OPg, and OPb of the pixel defining layer 380 and the second openings OPBMr, OPBMg, and OPBMb of the light blocking layer 220 are formed in a circular shape, and the scattering layer 210 is not formed. Comparative Example 4 is a comparative example in which the openings OPr, OPg, and OPb of the pixel defining layer 380 and the second openings OPBMr, OPBMg, and OPBMb of the light blocking layer 220 are formed in an elliptical shape and the scattering layer 210 is not formed.

In FIG. 14, Embodiment 3 is identical to Embodiment 3 of FIG. 9, and the three Embodiment 3s included in FIG. 14 are each formed with different haze values for the scattering layer. Embodiment 4 has the same planar shape as the example of FIG. 12 (2 μm) in FIG. 13, and the haze value of the scattering layer is 40%. In Embodiment 5, similar to Embodiment 4, the openings OPr, OPg, and OPb of the pixel defining layer 380, the openings OPSLr, OPSLg, and OPSLb of the scattering layer 210, and the second openings OPBMr, OPBMg, and OPBMb of the light blocking layer 220 are all formed in an elliptical shape, but the overlapping interval between the openings OPr, OPg, and OPb of the pixel defining layer 380 and the openings OPSLr, OPSLg, and OPSLb of the scattering layer 210 is 0 μm (e.g., the widths of openings OPr, OPg, and OPb are equal to the widths of openings OPSLr, OPSLg, and OPSLb in plan view) so that the openings OPr, OPg, and OPb of the pixel defining layer 380 and the openings OPSLr, OPSLg, and OPSLb of the scattering layer 210 completely coincide in a plan view. In Embodiment 5, the haze value of the scattering layer is also 40%.

In FIG. 14, the halo characteristics, diffraction characteristics, and reflection characteristics according to the type of light (square light or linear light) are also shown for various comparative examples and examples as described above.

First, it may be seen that the halo characteristics are the cleanest in Comparative Example 3 and Comparative Example 4, which do not have a scattering layer. However, it may be confirmed that Comparative Example 3 and Comparative Example 4 show a large rainbow mura in the diffraction characteristics.

Hereinafter, a description will be given focusing on Comparative Example 1 and Embodiment 3 in which the opening shape is circular.

Although the halo characteristics of Comparative Example 1 are not as good as those of Comparative Example 3, it may be confirmed that rainbow mura is reduced in the diffraction characteristics, and it may be confirmed that rainbow mura is also reduced as the haze value increases.

However, it may be confirmed that Embodiment 3 has improved halo characteristics and diffraction characteristics compared to Comparative Example 1. Additionally, in the same Embodiment 3, it may be confirmed that the rainbow mura in the diffraction characteristics decreases as the haze value of the scattering layer increases.

For reference, it may be confirmed that there is no significant difference in the reflection characteristics for square lights and straight lights in Comparative Example 3, Comparative Example 1, and Embodiment 3.

The following will focus on Comparative Example 4, Embodiment 4, and Embodiment 5, which have an elliptical opening shape.

In Comparative Example 4, the halo characteristics are good, but there is a disadvantage in that rainbow mura is strongly visible in the diffraction characteristics. In contrast, in Embodiment 4 and Embodiment 5, it may be confirmed that the rainbow mura is reduced in the diffraction characteristics as a scattering layer is formed and an opening is formed in the scattering layer. Particularly, although Embodiment 5 and Embodiment 4 have the same haze value of the scattering layer, it may be confirmed that rainbow mura in the diffraction characteristics is reduced in Embodiment 4. That is, it may be confirmed that the structure of covering at least a portion of the openings OPr, OPg, and OPb of the pixel defining layer 380 with the scattering layer 210 reduces rainbow mura by scattering external light reflected from the anode.

It may be confirmed that there is no significant difference in the reflection characteristics for square lights and straight lights in Comparative Example 4, Embodiment 4, and Embodiment 5.

For reference, the haze value of the scattering layer may increase as the content of scattering particles 211 increases when changing the scattering particles 211 included in the scattering layer 210 or when using the same scattering particles 211.

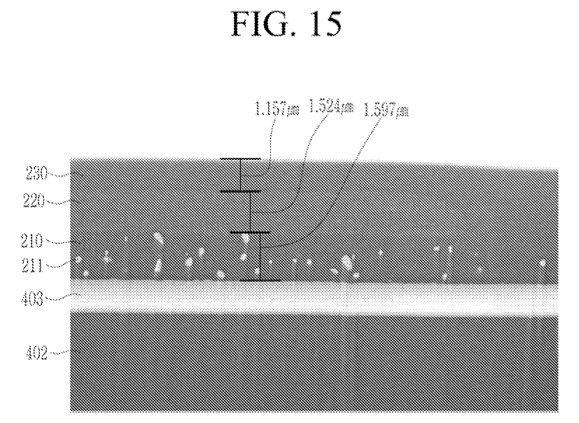

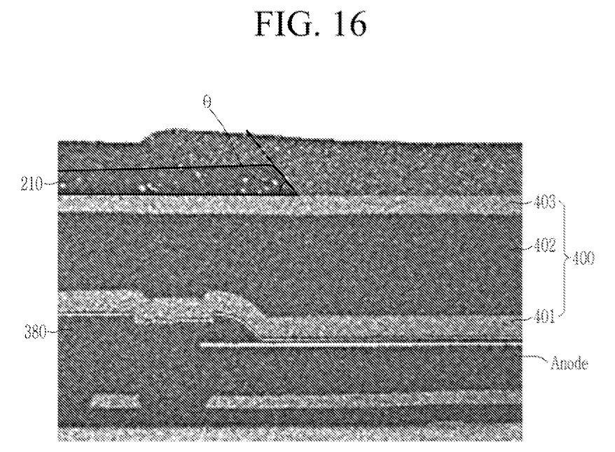

Hereinafter, the actual cross-sectional structure of a portion of a light emitting display device according to an embodiment will be described with reference to FIG. 15 and FIG. 16.

FIG. 15 and FIG. 16 are photographs capturing cross-sections of a portion of a display panel according to an embodiment.

First, FIG. 15 shows a cross-section of the organic encapsulation layer 402 and the second inorganic encapsulation layer 403 among the encapsulation layers, and the layers above them (scattering layer 210, scattering particles 211, light blocking layer 220, and color filter 230).

Referring to FIG. 15, it may be confirmed that the thickness of the scattering layer 210 according to an embodiment is 1.597 μm, the thickness of the light blocking layer 220 is 1.524 μm, and the thickness of the color filter 230 is 1.157 μm. While these thicknesses may vary depending on the embodiment, the thickness of the scattering layer 210 is comparable to that of the light blocking layer 220 and is formed to be slightly thicker than the light blocking layer 220 to sufficiently provide scattering characteristics for external light so that rainbow mura due to external light is not visible. The thickness of the scattering layer 210 may be formed to be 90% or more and 150% or less of the thickness of the light blocking layer 220, depending on the embodiment.

FIG. 16 is a cross-sectional photograph taken around the edge of the scattering layer 210, specifically, the edge of an opening of the scattering layer 210. In FIG. 16, an anode, a pixel defining layer 380, an encapsulation layer 400 including a first inorganic encapsulation layer 401, an organic encapsulation layer 402, and a second inorganic encapsulation layer 403, and the scattering layer 210 are shown.

The scattering layer 210 according to the embodiment of FIG. 16 is disposed on an upper surface of the second inorganic encapsulation layer 403 and has a structure protruding toward a front surface of the display device. Here, the scattering layer 210 is formed with a tapered edge, and the taper angle of the tapered edge of the scattering layer 210 is indicated as θ in FIG. 16. The taper angle θ may vary depending on the embodiment and may have an angle greater than 0 degrees and less than 90 degrees. Compared to a case in which the scattering layer is formed in a structure protruding toward a rear surface, which is opposite to the front surface, the scattering layer 210 of the embodiment in FIG. 16 is not only easy to manufacture using an exposure and development process of a photolithography method, but also easy to adjust the taper angle, which may effectively reduce rainbow mura described later.

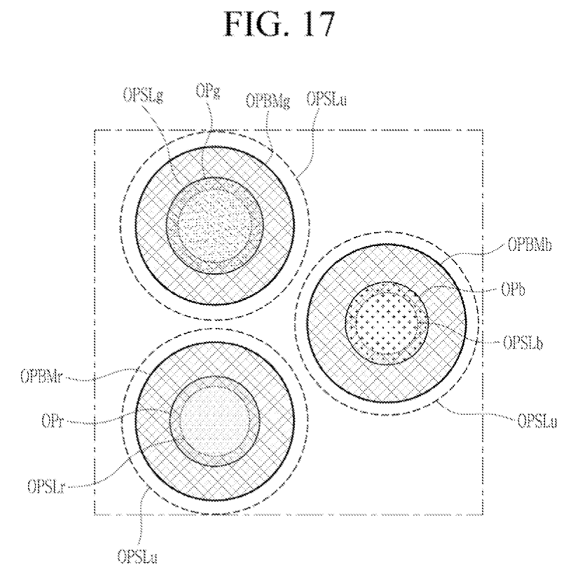

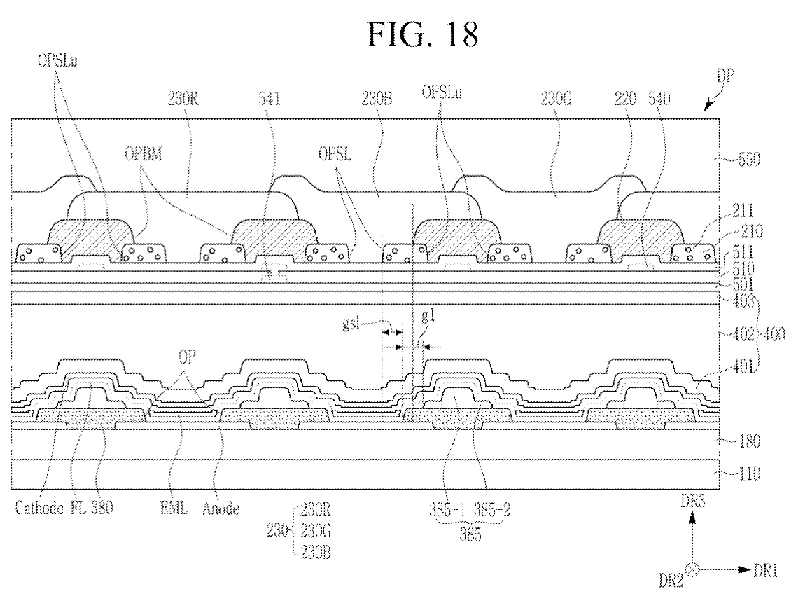

As shown in FIG. 7, the scattering layer 210 described above has a structure in which the entire scattering layer 210 is formed in a region in which the light blocking layer 220 is disposed. However, in some embodiments, the scattering layer 210 may not be formed in a partial region within the region in which the light blocking layer 220 is formed, and such an embodiment will be described with reference to FIG. 17 and FIG. 18.

FIG. 17 is a plan view of a portion of a display panel according to some embodiments, and FIG. 18 is a schematic cross-sectional view of a display panel according to the embodiment of FIG. 17.

First, the planar structure of FIG. 17 is described.

Comparing FIG. 17 with FIG. 8, it may be confirmed that FIG. 17 additionally includes an inner opening OPSLu of the scattering layer 210 outside the second opening OPBMr, OPBMg, or OPBMb of the light blocking layer 220. In FIG. 17, the inner opening OPSLu of the scattering layer 210 is larger than the second opening OPBMr, OPBMg, or OPBMb of the light blocking layer 220, and is therefore covered by the light blocking layer 220. Accordingly, the inner opening OPSLu of the scattering layer 210 is shown with a dashed line because it is covered by the light blocking layer 220. Referring to FIG. 17, the scattering layer 210 exists only outside the opening OPSLr, OPSLg, or OPSLb of the scattering layer 210 and inside the inner opening OPSLu. As a result, the plane shape of the scattering layer 210 may have a planar shape similar to a ring shape.

The specific structure will be described through the cross-sectional view of FIG. 18.

FIG. 18 differs from FIG. 7 only in the structure of the scattering layer 210, and the scattering layer 210 of FIG. 18 further includes the inner opening OPSLu, where the scattering layer 210 is not formed in a portion of the region in which the light blocking layer 220 is disposed. As a result, the light blocking layer 220 has a structure in which the layer disposed below the scattering layer 210, that is, in the embodiment of FIG. 18, is in direct contact with the third sensing insulating layer 511 through the inner opening OPSLu of the scattering layer 210.

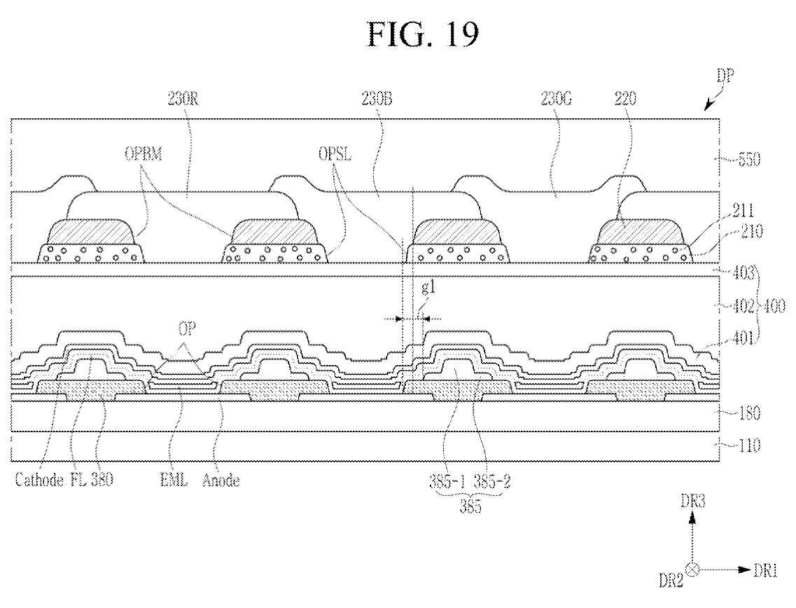

Hereinafter, an embodiment having a different cross-sectional structure from that of FIG. 7 will be described with reference to FIG. 19.

FIG. 19 is a schematic cross-sectional view of a display panel according to some embodiments.

First, unlike the embodiment of FIG. 7, the embodiment of FIG. 19 does not include the sensing insulating layers 501, 510, and 511 and the plurality of sensing electrodes 540 and 541 formed for touch sensing between the encapsulation layer 400 and the scattering layer 210. As a result, the scattering layer 210, the light blocking layer 220, and the color filters 230R, 230G, and 230B are disposed on the encapsulation layer 400, the second inorganic encapsulation layer 403 may contact the scattering layer 210, and the upper structure of the scattering layer 210 and the lower structure of the encapsulation layer 400 may be the same as in FIG. 7.

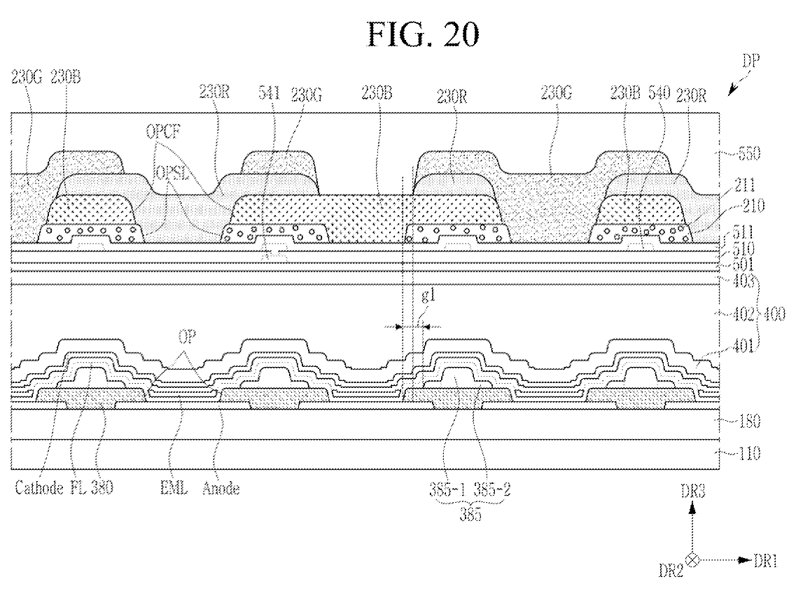

In some embodiments, at least two color filters 230R, 230G, and 230B may form a light blocking area of overlapping color filters, instead of the light blocking layer 220. Hereinafter, embodiments that do not include a light blocking layer and include a light blocking area in which at least two color filters 230R, 230G, and 230B overlap will be described with reference to FIG. 20 to FIG. 23.

First, a modified structure of FIG. 7 will be described with reference to FIG. 20 to FIG. 22.

FIGS. 20, 21 and 22 are schematic cross-sectional views of a display panel according to some embodiments.

Hereinafter, the structure of a light emitting display panel DP according to an embodiment will be first described with reference to FIG. 20, and descriptions of the same constituent elements as those in FIG. 7 may be omitted.

The light emitting display panel DP according to the embodiment of FIG. 20 may display an image by forming a light emitting diode on the substrate 110, and may include a plurality of sensing electrodes 540 and 541 to sense a touch, and light emitted from the light emitting diode by including the color filters 230R, 230G, and 230B has color characteristics of the color filters 230R, 230G, and 230B. A light blocking layer formed in black to block visible light may not be formed, and instead of the light blocking layer, at least two or more color filters may be overlapped to block visible light.

A region in which at least two or more color filters overlap to block visible light is referred to as a light blocking area, and in the embodiment of FIG. 20, the blue color filter 230B, the red color filter 230R, and the green color filter 230G are sequentially stacked. The order in which color filters are stacked may vary depending on the embodiment.

In addition, a polarizing plate is not formed on the front surface of the light emitting display panel DP according to the embodiment of FIG. 20, and instead, a pixel defining layer 380 is formed with a black organic material, and a light blocking area in which at least two color filters overlap is formed on the upper portion of the pixel defining layer 380 so that even if external light is incident on the inside, it is not reflected from the anode or the like and transmitted to the user.

Specifically, the color filters 230R, 230G, and 230B are disposed on the third sensing insulating layer 511. The color filters 230R, 230G, and 230B include a red color filter 230R that transmits red light, a green color filter 230G that transmits green light, and a blue color filter 230B that transmits blue light. Each of the color filters 230R, 230G, and 230B may be disposed to overlap the anode (Anode) of the light emitting diode in a plan view. Since light emitted from the light emitting layer EML may be emitted while changing to the corresponding color as it passes through the color filter, all light emitted from the light emitting layer EML may have the same color. However, light of different colors is displayed in the light emitting layer EML, and the displayed color may be enhanced by passing through a color filter of the same color.

In some embodiments, the color filters 230R, 230G, and 230B may be replaced with a color conversion layer, or may further include a color conversion layer. The color conversion layer may include a quantum dot.

In the embodiment of FIG. 20, the light blocking layer formed in black to block visible light is not formed, and instead of the light blocking layer, the light blocking area formed by overlapping at least two or more color filters is formed to replace the light blocking layer. In the embodiment of FIG. 20, the light blocking area has the blue color filter 230B, the red color filter 230R, and the green color filter 230G sequentially stacked. The order in which color filters are stacked may vary depending on the embodiment.

The light blocking area, in which at least two or more color filters overlap, may be disposed to overlap the sensing electrodes 540 and 541 in a plan view, and may be disposed so as not to overlap the anode (Anode) in a plan view. This is to prevent the anode (Anode) and the light emitting layer EML capable of displaying an image from being covered by the light blocking area and the sensing electrodes 540 and 541.

Referring to FIG. 20, the light blocking area of the color filter, in which three color filters overlap, is disposed only in a region that overlaps (e.g., is directly above) the pixel defining layer 380 in a plan view, and one side of the light blocking area of the color filter is disposed inwardly from a corresponding side of the pixel defining layer 380.

Only one color filter may be disposed in a region excluding the light blocking area, and light of the color of the corresponding color filter is transmitted to form the light transmitting region of the color filter. That is, multiple color filters may overlap in plan view to form a light blocking area, but only one color filter may be disposed in the opening (OPSL, OPCF, etc.). Hereinafter, the light transmitting region of the color filter, where only one color filter is disposed, may also be referred to as a second opening OPCF of the light blocking area, as light is transmitted therethrough. The second opening OPCF of the light blocking area is an opening disposed in the light blocking area where at least two or more color filters overlap, and may correspond to a region where only one color filter is disposed. The second opening OPCF of the light blocking area of the color filter may correspond to the second opening OPBM of the light blocking layer 220 described above. As a result, the second opening OPCF of the light blocking area of the color filter may have a circular or elliptical planar shape.

The area of the second opening OPCF of the light blocking area is formed larger than the opening OP of the pixel defining layer 380, and the opening OP of the pixel defining layer 380 may be disposed within the second opening OPCF of the light blocking area in a plan view. The opening OPSL of the scattering layer 210 may be disposed within the second opening OPCF of the light blocking area, and in some embodiments, a portion of the opening OPSL of the scattering layer 210 may be disposed outside the second opening OPCF of the light blocking area. In addition, the opening OPSL of the scattering layer 210 may be disposed inside or outside the opening OP of the pixel defining layer 380, so the opening OPSL of the scattering layer 210 may be disposed within the opening OP of the pixel defining layer 380 in a plan view, or the opening OP of the pixel defining layer 380 may be disposed within the opening OPSL of the scattering layer 210. In some embodiments, a portion of the opening OPSL of the scattering layer 210 may be disposed inside the opening OP of the pixel defining layer 380 in a plan view, and the remaining portion thereof may be disposed outside the opening OP of the pixel defining layer 380.

Even in the embodiment of FIG. 20, the opening OPSL of the scattering layer 210 may have an edge position range gsl-r corresponding to FIG. 10. That is, the maximum edge position range gsl-b is a position at a horizontal distance of 1 μm inward from the edge of the second opening OPCF of the light blocking area of the color filter, and the minimum edge position range gsl-a is a position at a horizontal distance of 10 μm inward from the edge of the opening OP of the pixel defining layer 380. Therefore, the opening OPSL of the scattering layer 210 may be smaller by 1 µm or more than the second opening OPCF of the light blocking area of the color filter, and may be smaller by 10 µm or less than the openings OPr, OPg, and OPb of the pixel defining layer 380.

In addition, one side of the spacer 385 is also disposed inwardly by a predetermined gap g1 from a corresponding side of the pixel defining layer 380, and the spacer 385 is also disposed inwardly with respect to one side of the light blocking area. As a result, when viewed from the front of the display panel DP, the spacer 385 may not be visible because it is covered by the light blocking area.

When external light is incident, it may pass through the second opening OPCF of the light blocking area of the color filter and the opening OPSL of the scattering layer 210, and then be reflected by the sidewall of the opening OP of the pixel defining layer 380. The sidewall of the opening OP of the pixel defining layer 380 is curved so that color separation occurs depending on the reflected position, and a rainbow mura may occur in which the colors of the reflected light appear in various colors like a rainbow. Such rainbow mura may be easily noticeable to the user, thereby degrading display quality, but in the present embodiment, the scattering layer 210 having the opening OPSL is formed, and the opening OPSL of the scattering layer 210 may be formed 1 μm or more smaller than the second opening OPCF of a light blocking area of the color filter, and 10 μm or less smaller than the openings OPr, OPg, and OPb of the pixel defining layer 380 so that the rainbow mura may be removed or made less noticeable, making it difficult for the user to easily see rainbow mura.

In addition, in some embodiments, the shape, size, and angle of the opening OPSL of the scattering layer 210 may be varied, and a plurality of different openings OPSL of the scattering layer 210 may be included in a single panel to prevent reflected external light from forming a specific diffraction pattern.

The planarization layer 550 covering the color filters 230R, 230G, and 230B is disposed on the color filters 230R, 230G, and 230B. The planarization layer 550 is for planarizing the upper surface of the light emitting display panel, and may be a transparent organic insulating layer including one or more materials selected from the group including polyimide, polyamide, an acrylic resin, benzocyclobutene, and a phenol resin.

In some embodiments, a low refractive layer and an additional planarization layer may be further disposed on the planarization layer 550 in order to improve front visibility and light emitting efficiency of the display panel. Light may be emitted while being refracted to the front side by the low refractive layer and the additional planarization layer having high refractive characteristics. In this case, in some embodiments, the low refractive layer and the additional planarization layer may be directly disposed on the color filter while the planarization layer 550 is omitted.

In the present embodiment, no polarizing plate is formed on the planarization layer 550. That is, the polarizing plate may serve to prevent the display quality from being degraded while being recognized by the user due to external light being reflected from the anode (Anode) or the sidewall of the opening OP of the pixel defining layer 380. However, the polarizing plate not only reduces the reflection of external light, but also reduces the light emitted from the light emitting layer EML, so there is a disadvantage in that more power is consumed to display a certain brightness. In order to reduce power consumption, the light emitting display device of the present embodiment may not include a polarizing plate.

In addition, in the present embodiment, the side of the anode (Anode) is covered with the pixel defining layer 380 to reduce the degree of reflection from the anode (Anode), and the light blocking area in which at least two or more color filters are overlapped is also formed to reduce the degree of incident light, thereby already including a structure to prevent degradation of display quality due to reflection. Therefore, there is no need to form a polarizing plate separately on the front surface of the light emitting display panel DP.

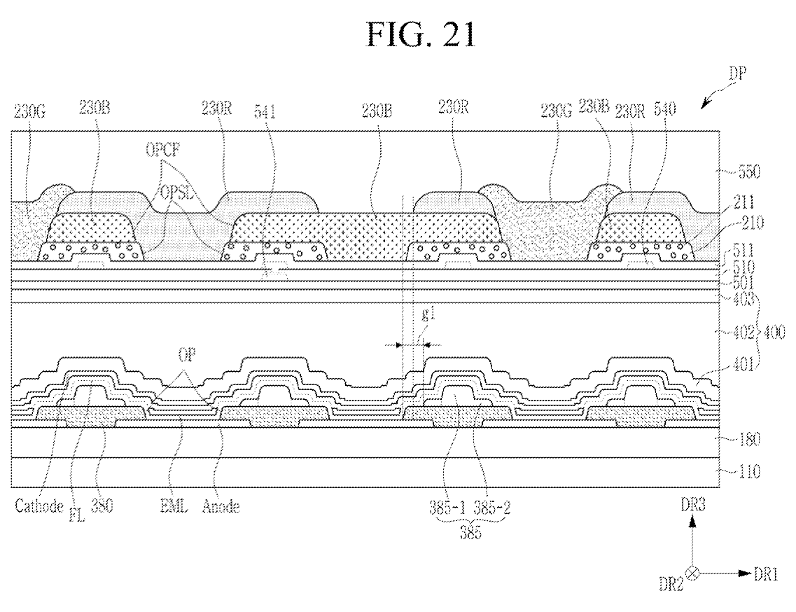

In the embodiment of FIG. 20, the light blocking area, in which at least two or more color filters are overlapped, has been mainly described as the embodiment in which three color filters are overlapped. However, in some embodiments, two color filters may be overlapped to form the light blocking area of the color filter, as illustrated in FIG. 21.

FIG. 21 is a diagram corresponding to FIG. 7 and FIG. 20, and only the color filters 230R, 230G, and 230B are different from those of FIG. 20, so the lower structure of the third sensing insulating layer 511 is the same as that of FIG. 20. Hereinafter, the upper structure of the third sensing insulating layer 511, which differs from FIG. 20, will be mainly described.

Referring to FIG. 21, a light blocking layer for blocking visible light is not formed, and a blue color filter 230B and a red color filter 230R are sequentially overlapped to block visible light. The order in which color filters are stacked may vary depending on the embodiment.

Specifically, the light blocking area, where two color filters are overlapped, has the blue color filter 230B and the red color filter 230R overlapping, and a partial region of the light blocking area of the color filter also have a portion where the green color filter 230G is overlapped. However, unlike the embodiment of FIG. 20, the green color filter 230G is not formed over the entire light shielding area of the color filter, and thus, this is an embodiment in which the light blocking area of the color filter is formed with only two color filters. The light blocking area, in which two color filters overlap, is disposed only in a region that overlaps (e.g., is above) the pixel defining layer 380 in a plan view, and one side of the light blocking area of the color filter is disposed inwardly from a corresponding side of the pixel defining layer 380.

In regions other than the light blocking area of the color filter, only a single color filter may be disposed, and light of the color of the corresponding color filter is transmitted to form a light transmitting region of the color filter or a second opening OPCF of the light blocking area of the color filter. The area of the second opening OPCF is formed larger than the opening OP of the pixel defining layer 380, and the opening OP of the pixel defining layer 380 may be disposed within the second opening OPCF of the light blocking area of the color filter in a plan view. The opening OPSL of the scattering layer 210 may be disposed within the second opening OPCF of the light blocking area, and in some embodiments, a portion of the opening OPSL of the scattering layer 210 may be disposed outside the second opening OPCF of the light blocking area. In addition, the opening OPSL of the scattering layer 210 may be disposed inside or outside the opening OP of the pixel defining layer 380 in plan view, so the opening OPSL of the scattering layer 210 may be disposed within the opening OP of the pixel defining layer 380 in a plan view, or the opening OP of the pixel defining layer 380 may be disposed within the opening OPSL of the scattering layer 210. In some embodiments, a portion of the opening OPSL of the scattering layer 210 may be disposed inside the opening OP of the pixel defining layer 380 in a plan view, and the remaining portion thereof may be disposed outside the opening OP of the pixel defining layer 380.

The light blocking area of the color filter also overlaps (e.g., is directly above) the scattering layer 210, the spacer 385, and the plurality of sensing electrodes 540 and 541 in a plan view, in addition to the pixel defining layer 380. Specifically, in the light blocking area of the color filter, one side of the spacer 385 is also disposed inwardly by a predetermined gap g1 from a corresponding side of the pixel defining layer 380, and the spacer 385 is also disposed inwardly with respect to one side of the light blocking area of the color filter. Additionally, the plurality of sensing electrodes 540 and 541 are covered by the light blocking area of the color filter in a plan view. As a result, when viewed from the front of the display panel DP, the spacer 385 and the plurality of sensing electrodes 540 and 541 may not be visible due to being covered by the light blocking area of the color filter.

Even in the embodiment of FIG. 21, the opening OPSL of the scattering layer 210 may have an edge position range gsl-r corresponding to FIG. 10. That is, the maximum edge position range gsl-b is a position at a horizontal distance of 1 μm inward from the edge of the second opening OPCF of the light blocking area of the color filter, and the minimum edge position range gsl-a is a position at a horizontal distance of 10 μm inward from the edge of the opening OP of the pixel defining layer 380. Therefore, the opening OPSL of the scattering layer 210 may be smaller by 1 µm or more than the second opening OPCF of the light blocking area of the color filter, and may be smaller by 10 µm or less than the openings OPr, OPg, and OPb of the pixel defining layer 380. As a result, rainbow mura may be eliminated or made to appear weakly, making it difficult for the user to easily recognize the rainbow mura.

In some embodiments, the color filters 230R, 230G, and 230B may be replaced with a color conversion layer, or may further include a color conversion layer. The color conversion layer may include a quantum dot.

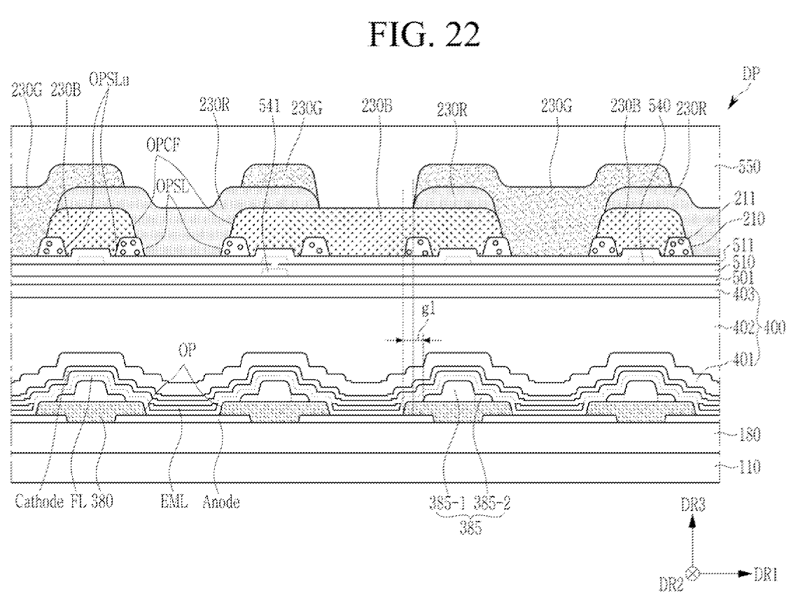

In some embodiments, as in the embodiments of FIG. 17 and FIG. 18, an inner opening OPSLu may be further formed in the scattering layer 210, and an embodiment in which the scattering layer 210 further includes an inner opening OPSLu will be described with reference to FIG. 22.

As in FIG. 20, FIG. 22 shows three color filters 230R, 230G, and 230B overlapping to form a light blocking area of the color filter.

The portion of FIG. 22 that is different from FIG. 20 is the scattering layer 210. The scattering layer 210 further includes an inner opening OPSLu, where the scattering layer 210 is not formed in a portion of the region in which the light blocking layer 220 is disposed. As a result, the light blocking layer 220 has a structure in which the layer disposed below the scattering layer 210 is in direct contact with the third sensing insulating layer 511 through the inner opening OPSLu of the scattering layer 210.

In some embodiments, the light blocking area of the color filter may be formed by overlapping only two of the three color filters 230R, 230G, and 230B while the scattering layer 210 has the inner opening OPSLu.

Even in the embodiment of FIG. 22, the opening OPSL of the scattering layer 210 may have an edge position range gsl-r corresponding to FIG. 10. That is, the maximum edge position range gsl-b is a position at a horizontal distance of 1 μm inward from the edge of the second opening OPCF of the light blocking area of the color filter, and the minimum edge position range gsl-a is a position at a horizontal distance of 10 μm inward from the edge of the opening OP of the pixel defining layer 380. Therefore, the opening OPSL of the scattering layer 210 may be smaller by 1 µm or more than the second opening OPCF of the light blocking area of the color filter, and may be smaller by 10 µm or less than the openings OPr, OPg, and OPb of the pixel defining layer 380. As a result, rainbow mura may be eliminated or made to appear weakly, making it difficult for the user to easily recognize the rainbow mura.

In some embodiments, the color filters 230R, 230G, and 230B may be replaced with a color conversion layer, or may further include a color conversion layer. The color conversion layer may include a quantum dot.

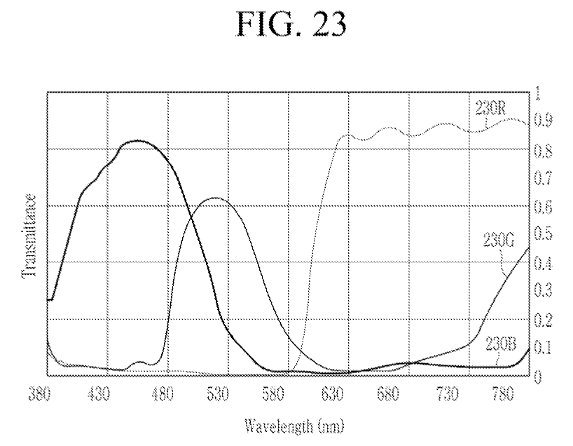

Hereinafter, with reference to FIG. 23, it will be described whether two color filters may be stacked to substitute for the role of the light blocking layer.

FIG. 23 is a graph showing transmittance of a color filter according to wavelength.

FIG. 23 is a graph of the transmittance for the wavelength of each of the color filters 230R, 230G, and 230B, so light in the wavelength range indicated at a high value is transmitted. Referring to FIG. 23, it may be confirmed that, except for the wavelength band transmitted by each color filter 230R, 230G, or 230B, other portions have a transmittance of less than 10%, and when three or two color filters are overlapped, almost no wavelength band is transmitted. Therefore, it may be confirmed that overlapping at least two color filters may substitute for the function of a light blocking layer, and that overlapping three color filters as in FIG. 20 or FIG. 22, or overlapping two color filters as in FIG. 21, may substitute for a light blocking layer.

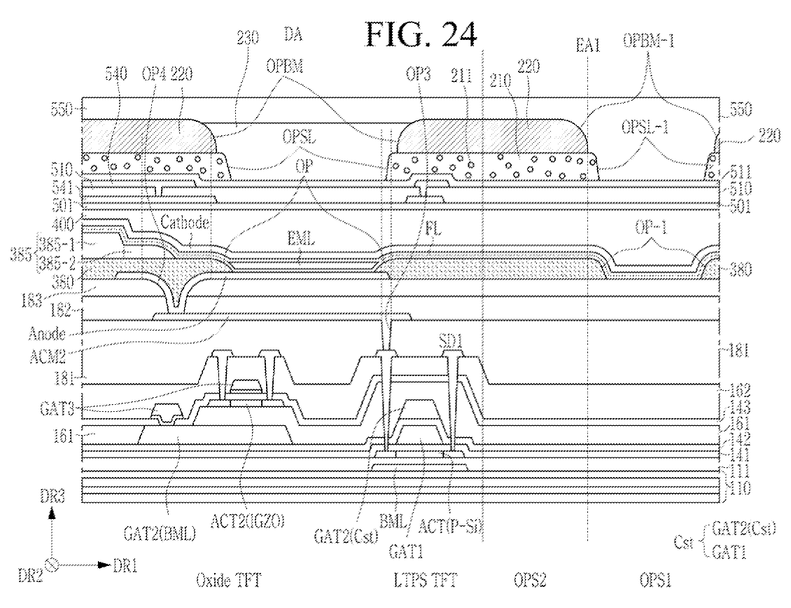

Hereinafter, the stacked structure of the display area DA and the first component area EA1 will be described in more detail with reference to FIG. 24 to FIG. 27.

FIGS. 24, 25, 26 and 27 are cross-sectional views of a light emitting display device according to an embodiment.

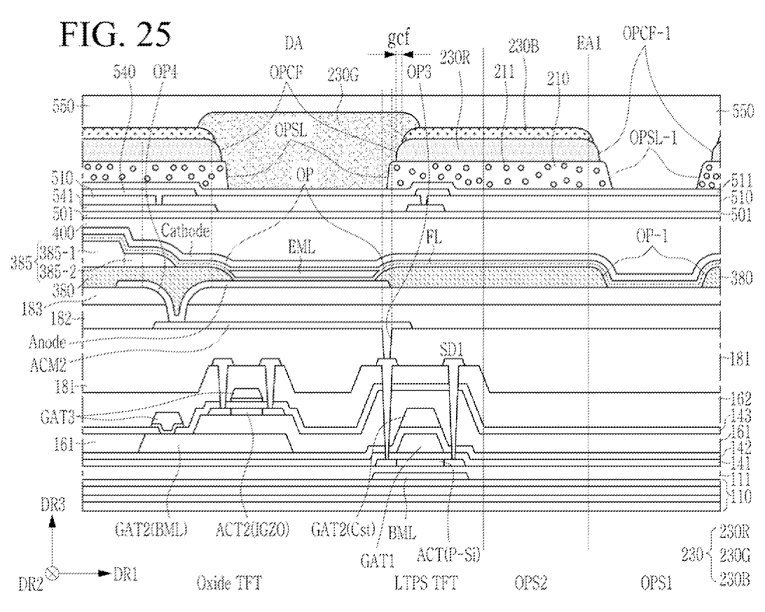

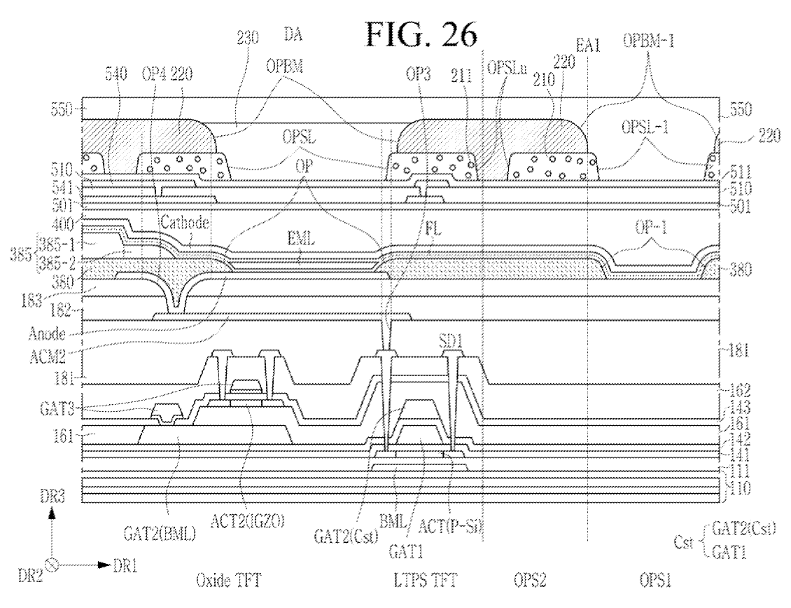

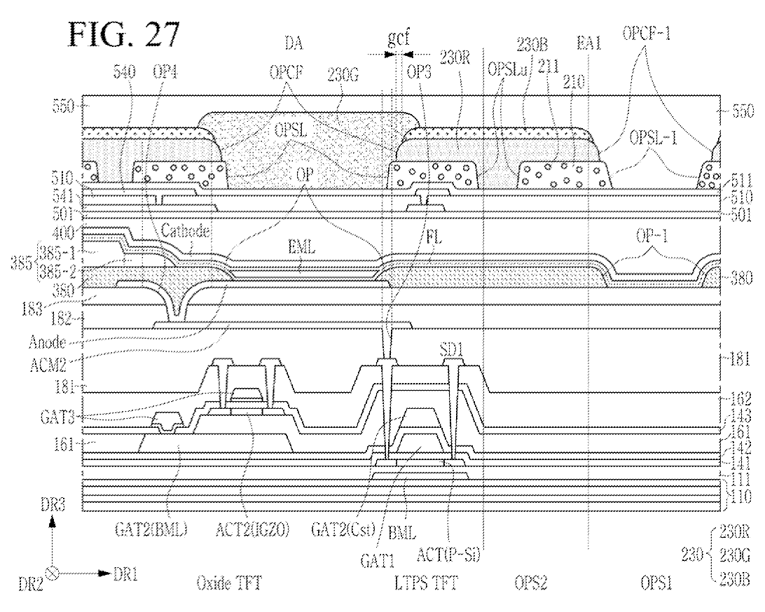

FIG. 24 illustrates an embodiment including a light blocking layer 220, and FIG. 25 illustrates an embodiment in which a light blocking area of a color filter is formed by overlapping a blue color filter 230B and a red color filter 230R instead of the light blocking layer 220. In addition, FIG. 26 illustrates an embodiment in which the scattering layer 210 further includes an inner opening OPSLu in the embodiment of FIG. 24, and FIG. 27 illustrates an embodiment in which the scattering layer 210 further includes an inner opening OPSLu in the embodiment of FIG. 25.

First, the embodiment of FIG. 24 will be described in detail.

The light emitting display device may largely be divided into a lower panel layer and an upper panel layer, and the lower panel layer is a portion in which a light emitting diode and a pixel circuit portion configuring the pixel are disposed, and the lower panel may also include an encapsulation layer 400 covering them. Here, the pixel circuit portion may include a second organic layer 182 and a third organic layer 183 and may refer to a configuration thereunder, and the light emitting diode may refer to a configuration disposed on the third organic layer 183 and under the encapsulation layer 400. A structure disposed above the encapsulation layer 400 may correspond to the upper panel layer.

Referring to FIG. 24, a metal layer BML is disposed on a substrate 110.

The substrate 110 may include a material that has rigid characteristics such as glass and thus does not bend, or may include a flexible material such as plastic or polyimide that may be bent. In the case of a flexible substrate, as shown in FIG. 24, the structure may have a two-layered structure that has polyimide and a barrier layer formed of an inorganic insulating material thereon.

The metal layer BML may be formed at a position overlapping a channel of a driving transistor T1 in a plan view among subsequent first semiconductor layers, and it is also referred to as a lower shielding layer. The metal layer BML may include a metal such as copper (Cu), molybdenum (Mo), aluminum (Al), and titanium (Ti), or a metal alloy thereof.

A buffer layer 111 covering the substrate 110 and the metal layer BML is disposed thereon. The buffer layer 111 serves to block penetration of impure elements into a first semiconductor layer ACT(P-Si), and may be an inorganic insulating layer including silicon oxide (SiOx), silicon nitride (SiNx), or silicon oxynitride (SiONx).

The first semiconductor layer ACT(P-Si) formed of a silicon semiconductor (for example, a polycrystalline semiconductor (P-Si)) is disposed on the buffer layer 111. The first semiconductor layer ACT(P-Si) includes a channel of a polycrystalline transistor (LTPS TFT) including a driving transistor T1, and a first area and a second area disposed at both sides thereof. Here, the polycrystalline transistor (LTPS TFT) may include various switching transistors or compensation transistors in addition to the driving transistor T1. In addition, both sides of the channel of the first semiconductor layer ACT(P-Si) have an area having a conductive layer characteristic by plasma treatment or doping so that it may serve as a first electrode and a second electrode of a transistor.

A first gate insulating layer 141 may be disposed on the first semiconductor layer ACT(P-Si). The first gate insulating layer 141 may be an inorganic insulating layer including silicon oxide (SiOx), silicon nitride (SiNx), or silicon oxynitride (SiONx).

A first gate conductive layer GAT1 including a gate electrode of the polycrystalline transistor (LTPS TFT) may be disposed on the first gate insulating layer 141. The first gate conductive layer GAT1 may have a first scan line or a light emitting control line formed in addition to the gate electrode of the polycrystalline transistor (LTPS TFT). The first gate conductive layer may include a metal such as copper (Cu), molybdenum (Mo), aluminum (Al), or titanium (Ti) or a metal alloy thereof, and may be formed as a single layer or multilayer.

After forming the first gate conductive layer GAT1, a plasma treatment or doping process may be performed to make the exposed region of the first semiconductor layer conductive. That is, the first semiconductor layer ACT(P-Si) covered by the first gate conductive layer GAT1 is not made to be conductive, and a portion of the first semiconductor layer ACT(P-Si) not covered by the first gate conductive layer GAT1 may have the same characteristics as the conductive layer.

A second gate disposed on the first gate conductive layer GAT1 and the first gate insulating layer 141 may be an inorganic insulating layer including silicon oxide (SiOx), silicon nitride (SiNx), or silicon oxynitride (SiONx).

A second gate conductive layer including one electrode GAT2(Cst) of a storage capacitor Cst and a lower shielding layer GAT2(BML) of an oxide transistor (Oxide TFT) may be disposed on the second gate insulating layer 142. The lower shielding layer GAT2(BML) of the oxide transistor (Oxide TFT) is disposed below the channel of the oxide transistor (Oxide TFT), and may serve as a shield from light or electromagnetic interference provided to the channel from a lower side thereof. One electrode GAT2(Cst) of the storage capacitor Cst overlaps (e.g., is above) a gate electrode of the driving transistor T1 to form the storage capacitor Cst. In some embodiments, the second gate conductive layer may further include a scan line, a control line, or a voltage line. The second gate conductive layer may include a metal such as copper (Cu), molybdenum (Mo), aluminum (Al), or titanium (Ti) or a metal alloy thereof, and may be formed as a single layer or multilayer.

A first interlayer insulating layer 161 may be disposed on the second gate conductive layer. The first interlayer insulating layer 161 may include an inorganic insulating layer including silicon oxide (SiOx), silicon nitride (SiNx), and silicon oxynitride (SiONx), and in some embodiments, the inorganic insulating material may be thickly formed therein.

An oxide semiconductor layer ACT2(IGZO) including a channel, a first area, and a second area of the oxide transistor (Oxide TFT) may be disposed on the first interlayer insulating layer 161.

A third gate insulating layer 143 may be disposed on the oxide semiconductor layer ACT2(IGZO). The third gate insulating layer 143 may be disposed on an entire surface of the oxide semiconductor layer ACT2(IGZO) and the first interlayer insulating layer 161. The third gate insulating layer 143 may include an inorganic insulating layer including silicon oxide (SiOx), silicon nitride (SiNx), or silicon oxynitride (SiONx).

A third gate conductive layer GAT3 including a gate electrode of the oxide transistor (Oxide TFT) may be disposed on the third gate insulating layer 143. The gate electrode of the oxide transistor (Oxide TFT) may overlap the channel. The third gate conductive layer GAT3 may further include a scan line or a control line, and additionally may include a connecting electrode connected to the lower shielding layer GAT2(BML) of the oxide transistor (Oxide TFT). The third gate conductive layer GAT3 may include a metal such as copper (Cu), molybdenum (Mo), aluminum (Al), or titanium (Ti), or a metal alloy thereof, and may be formed as a single layer or multilayer.

A second interlayer insulating layer 162 may be disposed on the third gate conductive layer GAT3. The second interlayer insulating layer 162 may have a single layer or multi-layer structure. The second interlayer insulating layer 162 may include an inorganic insulating material such as silicon nitride (SiNx), silicon oxide (SiOx), and silicon oxynitride (SiOxNy), and in some embodiments, it may include an organic material.

A first data conductive layer SD1 including a connecting electrode capable of being connected to the first area and the second area of each of the polycrystalline transistor (LTPS TFT) and the oxide transistor (Oxide TFT) may be disposed on the second interlayer insulating layer 162. The first data conductive layer SD1 may include a metal such as aluminum (Al), copper (Cu), molybdenum (Mo), or titanium (Ti) or a metal alloy thereof, and may be formed as a single layer or multilayer.

A first organic layer 181 may be disposed on the first data conductive layer SD1. The first organic layer 181 may be an organic insulating layer including an organic material, and the organic material may include one or more materials selected from the group including polyimide, polyamide, acrylic resin, benzocyclobutene, and phenol resin.

A second data conductive layer including an anode connecting electrode ACM2 may be disposed on the first organic layer 181. The second data conductive layer may include a data line or a driving voltage line. The second data conductive layer SD2 may include a metal such as aluminum (Al), copper (Cu), molybdenum (Mo), or titanium (Ti) or a metal alloy thereof, and may be formed as a single layer or a multilayer.

The second organic layer 182 and the third organic layer 183 are disposed on the second data conductive layer, and an opening OP4 for anode connection is formed in the second organic layer 182 and the third organic layer 183. The anode connecting electrode ACM2 is electrically connected to an anode through the opening OP4 for anode connection. The second organic layer 182 and the third organic layer 183 may be organic insulating layers and may include one or more materials selected from the group including polyimide, polyamide, acrylic resin, benzocyclobutene, and phenol resin. In some embodiments, the third organic layer 183 may be omitted.

A pixel defining layer 380 covering at least a portion of the anode (Anode) while having the opening OP exposing the anode (Anode) may be disposed on the anode (Anode). The pixel defining layer 380 may be a black pixel defining layer that is made of an organic material having a black color so that light applied from the outside is not reflected back to the outside, and in some embodiments, it may be made of a transparent organic material. Therefore, in some embodiments, the pixel defining layer 380 may include a black organic material of a negative type, and may include a black pigment.

A spacer 385 is disposed on the pixel defining layer 380. The spacer 385 may include a first portion 385-1 disposed in a high and narrow area and a second portion 385-2 disposed in a low and wide area. Unlike the pixel defining layer 380, the spacer 385 may be made of a transparent organic insulating material. In some embodiments, the spacer 385 may be made of a transparent organic material of a positive type.

On the anode (Anode), the spacer 385, and the pixel defining layer 380, the functional layer FL and the cathode (Cathode) are sequentially formed, and in the display area DA and first component area EA1, the functional layer FL and the cathode (Cathode) may be entirely disposed. A light emitting layer EML is disposed between the functional layers FL, and the light emitting layer EML may only be disposed within the opening OP of the pixel defining layer 380. Hereinafter, a combination of the functional layer FL and the light emitting layer EML may be referred to as an intermediate layer. The functional layer FL may include at least one auxiliary layer such as an electron injection layer, an electron transport layer, a hole transport layer, and a hole injection layer, and the hole injection layer and the hole transport layer may be disposed below the light emitting layer EML, and the electron transport layer and the electron injection layer may be disposed above the light emitting layer EML.

An encapsulation layer 400 is disposed on the cathode (Cathode). The encapsulation layer 400 includes at least one inorganic layer and at least one organic layer, and in some embodiments, it may have a triple-layer structure including a first inorganic encapsulation layer, an organic encapsulation layer, and a second inorganic encapsulation layer. The encapsulation layer 400 may be for protecting the light emitting layer EML from moisture or oxygen that may be introduced from the outside. In some embodiments, the encapsulation layer 400 may have a structure in which an inorganic layer and an organic layer are sequentially further stacked.

The sensing insulating layers 501, 510, and 511 and a plurality of sensing electrodes 540 and 541 are disposed on the encapsulation layer 400 for touch sensing. In the embodiment of FIG. 24, a touch may be sensed in a capacitive type by using two sensing electrodes 540 and 541.

Specifically, the first sensing insulating layer 501 is formed on the encapsulation layer 400, and the plurality of sensing electrodes 540 and 541 are formed thereon. The plurality of sensing electrodes 540 and 541 may be insulated from each other with the second sensing insulating layer 510 therebetween, and some may be electrically connected through an opening disposed in the second sensing insulating layer 510. Here, the sensing electrodes 540 and 541 may include a metal such as aluminum (Al), copper (Cu), silver (Ag), gold (Au), molybdenum (Mo), titanium (Ti), or tantalum (Ta), or a metal alloy thereof, and may be formed as a single layer or a multilayer. The third sensing insulating layer 511 is formed on the sensing electrode 540.

The scattering layer 210, the light blocking layer 220, and color filters 230R, 230G, and 230B are disposed on the third sensing insulating layer 511.

The scattering layer 210 may be disposed to overlap the pixel defining layer 380 and the sensing electrodes 540 and 541 in a plan view, a portion of the scattering layer 210 may overlap the anode (Anode) in a plan view, and another portion thereof may not overlap the anode (Anode). The scattering layer 210 may overlap the pixel defining layer 380 in a plan view. The scattering layer 210 includes scattering particles 211 capable of scattering light, and has an opening OPSL that overlaps (e.g., is directly above) at least a portion of the opening OP of the pixel defining layer 380 in a plan view. The size, shape, and arrangement direction of the opening OPSL of the scattering layer 210 may vary, and the opening OPSL of the scattering layer 210 may have the edge position range described in FIG. 10.

The light blocking layer 220 may be disposed so as to overlap the sensing electrodes 540 and 541 in a plan view. The light blocking layer 220 has the second opening OPBM, and the second opening OPBM of the light blocking layer 220 overlaps (e.g., is directly above) the opening OP of the pixel defining layer 380 in a plan view. In addition, the second opening OPBM of the light blocking layer 220 may be wider than the opening OP of the pixel defining layer 380. As a result, the anode (Anode) overlapping the opening OP of the pixel defining layer 380 (that is, being exposed by the opening OP of the pixel defining layer 380) may not be covered by the light blocking layer 220 in a plan view. This is to prevent the anodes (Anode) and the light emitting layer EML capable of displaying an image from being covered by the light blocking layer 220 and the sensing electrodes 540 and 541. The second opening OPBM of the light blocking layer 220 may be formed larger than the opening OPSL of the scattering layer 210, and at least a portion of the second opening OPBM of the light blocking layer 220 may overlap the opening OPSL of the scattering layer 210 in a plan view. In addition, the light blocking layer 220 has a structure that overlaps the opening OP4 for anode connection in a plan view, but does not overlap the opening OP3 of the first organic layer 181 in a plan view.

The color filters 230R, 230G, and 230B are disposed on the sensing insulating layers 501, 510, and 511, the scattering layer 210, and the light blocking layer 220. In some embodiments, the color filters 230R, 230G, and 230B may be replaced with a color conversion layer, or may further include a color conversion layer. The color conversion layer may include a quantum dot.

The planarization layer 550 covering the color filters 230R, 230G, and 230B may be disposed on the color filters 230R, 230G, and 230B, and in some embodiments, a low refractive layer and an additional planarization layer may be further disposed on the planarization layer 550 to improve frontal visibility and light output efficiency of the display device. Light may be emitted while being refracted to the front side by the low refractive layer and the additional planarization layer having a high refractive characteristic. In this case, in some embodiments, the low refractive layer and the additional planarization layer may be directly disposed on the color filter 230 while the planarization layer 550 is omitted.

In the present embodiment, no polarizing plate is formed on the planarization layer 550. That is, the polarizing plate may serve to prevent the display quality from being degraded while the user recognizes the external light while it is incident and reflected on the anode (Anode) and the like. However, in the present embodiment, the pixel defining layer 380 covers a lateral surface of the anode (Anode) to reduce a degree of reflection from the anode (Anode), and the scattering layer 210 and the light blocking layer 220 are also formed to reduce an incident degree of light so that it already includes a structure to prevent degradation of display quality due to reflection. Therefore, there is no need to form a polarizing plate separately on the front surface of the display panel DP.

FIG. 24 also illustrates a cross-sectional structure of the first component area EA1, which is formed to allow light to transmit through a portion of the display area DA, in addition to the stacked structure of the display area DA.

In FIG. 24, the first component area EA1 is divided into a first photosensor area OPS1 (also referred to as a transmissive photosensor area) and a second photosensor area OPS2 (also referred to as a non-transmissive photosensor area). Here, the first photosensor area OPS1 is an area formed to allow light to be transmitted, where additional openings OP-1, OPSL-1, and OPBM-1 are disposed so as not to overlap the pixel defining layer 380, the scattering layer 210, and the light blocking layer 220 in a plan view. In contrast, the second photosensor area OPS2 is an area formed to prevent light from being transmitted, by being formed to overlap the pixel defining layer 380, the scattering layer 210, and the light blocking layer 220 in a plan view. The first photosensor area OPS1 of the first component area EA1 may not include a layer that blocks light, such as a metal layer or a semiconductor layer, and the second photosensor area OPS2 of the first component area EA1 may also not include a layer that blocks light, such as a metal layer or a semiconductor layer, and in some embodiments, since light is not transmitted, a layer that blocks light, such as a metal layer or a semiconductor layer, may be disposed in some areas. For reference, the first optical element ES1 (refer to FIG. 2) is disposed on the rear surface of the first component area EA1, and the front surface of the light emitting display device may be sensed through the first photosensor area OPS1 disposed in the first component area EA1. Here, by adjusting the number of the first photosensor area OPS1 and the second photosensor area OPS2 in a single first component area EA1, a sensor disposed on the rear surface of the first component area EA1 may sense the front surface of the light emitting display device, and additionally, the reflective color sense of light in the first component area EA1 may be improved. As a result, in some embodiments, the first component area EA1 may be prevented from being viewed by the user as having a different reflectivity or reflective color sense from the display area surrounding the first component area EA1.

Specifically, the layered structure of the first component area EA1 is as follows.

The buffer layer 111, which is an inorganic insulating layer, is disposed on the substrate 110, and the first gate insulating layer 141 and the second gate insulating layer 142, which are inorganic insulating layers, are sequentially disposed thereon. In addition, the first interlayer insulating layer 161, the third gate insulating layer 143, and the second interlayer insulating layer 162, which are inorganic insulating layers, are sequentially stacked on the second gate insulating layer 142.

The first organic layer 181, the second organic layer 182, and the third organic layer 183, which are organic insulating layers, are sequentially stacked on the second interlayer insulating layer 162.

The functional layer FL may be disposed on the third organic layer 183, and the cathode (Cathode) may be disposed thereon.

The encapsulation layer 400 is disposed on the cathode (Cathode), and the sensing insulating layers 501, 510, and 511 are sequentially disposed thereon. The encapsulation layer 400 may have a triple-layer structure sequentially including an inorganic encapsulation layer, an organic encapsulation layer, and an inorganic encapsulation layer. In addition, all of the sensing insulating layers 501, 510, and 511 may be inorganic insulating layers.

The planarization layer 550 may be disposed on the sensing insulating layers 501, 510, and 511.

In the first component area EA1 as described above, the metal layer, the first semiconductor layer, the first gate conductive layer, the second gate conductive layer, the oxide semiconductor layer, the third gate conductive layer, the first data conductive layer, the second data conductive layer, and the anode are not disposed. In addition, the light emitting layer EML and the sensing electrodes 540 and 541 are not formed therein.

Also, the additional openings OP-1, OPSL-1, and OPBM-1 may be formed in the pixel defining layer 380, the scattering layer 210, and the light blocking layer 220 respectively within the first photosensor area OPS1 of the first component area EA1 so that the pixel defining layer 380, the scattering layer 210, and the light blocking layer 220 may not be formed. As a result, light may be transmitted through the first photosensor area OPS1 and may not be scattered. In contrast, the second photosensor area OPS2 of the first component area EA1 may have a structure in which light is not transmitted by overlapping the pixel defining layer 380 and the light blocking layer 220 because the additional openings OP-1, OPSL-1, and OPBM-1 are not disposed.

The embodiment in which a total of three organic layers are formed and the anode connecting opening is formed in the second organic layer and the third organic layer has been described above. However, at least two organic layers may be formed, and in this case, the anode connecting opening may be disposed in the upper organic layer disposed far from the substrate, and the lower organic layer opening may be disposed in the lower organic layer.

Below, with reference to FIG. 25, an embodiment will be described in which a light blocking area of a color filter is formed by overlapping a blue color filter 230B and a red color filter 230R instead of a light blocking layer 220.

In FIG. 25, a third sensing insulating layer 511 and a structure thereunder are the same as those in FIG. 24, so only the upper structure of the third sensing insulating layer 511, which is different from FIG. 24, will be described in detail as follows.

The color filters 230R, 230G, and 230B are disposed on the third sensing insulating layer 511. In the embodiment of FIG. 25, a light blocking layer is not included, and the function of the light blocking layer is performed by the overlapped color filters 230R and 230B, and the overlapped color filters 230R and 230B may be disposed to overlap the scattering layer 210 and the sensing electrodes 540 and 541 in a plan view. The overlapped color filters 230R and 230B have the second opening OPCF, and the second opening OPCF of the overlapped color filters 230R and 230B overlaps (e.g., is directly above) the opening OP of the pixel defining layer 380 and the opening OPSL of the scattering layer 210 in a plan view. Additionally, the second opening OPCF of the overlapped color filters 230R and 230B may be formed wider than the opening OP of the pixel defining layer 380. As a result, the anode (Anode) overlapping the opening OP of the pixel defining layer 380 (that is, being exposed by the opening OP of the pixel defining layer 380) may have a structure that is not covered by the overlapped color filters 230R and 230B in a plan view. This is to prevent the anodes (Anode) and the light emitting layer EML capable of displaying an image from being covered by the overlapped color filters 230R and 230B and the sensing electrodes 540 and 541. Additionally, the overlapped color filters 230R and 230B have a structure that overlaps the opening OP4 for anode connection in a plan view.

Among the overlapped color filters 230R and 230B, the width of the upper blue color filter 230B may be narrower than the width of the lower red color filter 230R by a color filter gap gcf, and in some embodiments, the color filter gap gcf may have a value of 0 μm or more and 2 μm or less. In some embodiments, as shown in FIG. 21, when all three color filters overlap to form a light blocking area of the color filter having the same characteristics as the light blocking layer, two adjacent and overlapping color filters may have a color filter gap gcf, and the color filter gap gcf may have a value of 0 μm or more and 2 μm or less.

The second opening OPCF of the overlapped color filters 230R and 230B may be formed larger than the opening OPSL of the scattering layer 210, and at least a portion of the second opening OPCF of the overlapped color filters 230R and 230B may overlap the opening OPSL of the scattering layer 210 in a plan view. The size, shape, and arrangement direction of the opening OPSL of the scattering layer 210 may vary, and the opening OPSL of the scattering layer 210 may have the edge position range described in FIG. 10. That is, the opening OPSL of the scattering layer 210 may be smaller by 1 µm or more than the second opening OPCF of the light blocking area of the color filter, and may be smaller by 10 µm or less than the openings OPr, OPg, and OPb of the pixel defining layer 380. As a result, rainbow mura may be eliminated or made to appear weakly, making it difficult for the user to easily recognize the rainbow mura.

Within the second opening OPCF of the overlapped color filters 230R and 230B, a single color filter may be disposed, and in FIG. 25, the green color filter 230G is disposed. In some embodiments, the color filters 230R, 230G, and 230B may be replaced with a color conversion layer, or may further include a color conversion layer. The color conversion layer may include a quantum dot.

The planarization layer 550 covering the color filters 230R, 230G, and 230B may be disposed on the color filters 230R, 230G, and 230B, and the low refractive layer and an additional planarization layer may be further disposed on the planarization layer 550 to improve frontal visibility and light output efficiency of the display device. In some embodiments, the low refractive layer and the additional planarization layer may be directly disposed on the color filter while the planarization layer 550 is omitted.

In the embodiment of FIG. 25, no polarizing plate is formed on the planarization layer 550. That is, the polarizing plate may serve to prevent the display quality from being deteriorated while a user recognizes the external light while it is incident and reflected on the anode (Anode) and the like. However, in the present embodiment, the pixel defining layer 380 covers a lateral surface of the anode (Anode) to reduce a degree of reflection from the anode (Anode), and the overlapped color filters 230R and 230B and the scattering layer 210 are also formed to reduce an incident degree of light so that it already includes a structure to prevent deterioration of display quality due to reflection. Therefore, there is no need to form a polarizing plate separately on the front surface of the display panel DP.

A cross-sectional structure of the first component area EA1 according to the embodiment of FIG. 25 may be as follows.

The first component area EA1 is divided into a first photosensor area OPS1 and a second photosensor area OPS2. Here, the first photosensor area OPS1 is an area formed to transmit light, in which additional openings OP-1, OPSL-1, and OPCF-1 are disposed so as not to overlap, in a plan view, the light blocking area of the color filter, which is formed by overlapping the pixel defining layer 380, the scattering layer 210, and at least two color filters. In contrast, the second photosensor area OPS2 is an area formed not to transmit light by being formed to overlap, in a plan view, the light blocking area of the color filter, which is formed by overlapping the pixel defining layer 380, the scattering layer 210, and at least two color filters. Both the first photosensor area OPS1 and the second photosensor area OPS2 of the first component area EA1 may not include a layer that blocks light, such as a metal layer or a semiconductor layer. For reference, the first optical element ES1 (refer to FIG. 2) is disposed on the rear surface of the first component area EA1, and the front surface of the light emitting display device may be sensed through the first photosensor area OPS1 disposed in the first component area EA1.

Specifically, the layered structure of the first component area EA1 is as follows.

The buffer layer 111, which is an inorganic insulating layer, is disposed on the substrate 110, and the first gate insulating layer 141 and the second gate insulating layer 142, which are the inorganic insulating layers, are sequentially disposed thereon. In addition, the first interlayer insulating layer 161, the third gate insulating layer 143, and the second interlayer insulating layer 162, which are inorganic insulating layers, are sequentially stacked on the second gate insulating layer 142.

The first organic layer 181, the second organic layer 182, and the third organic layer 183, which are organic insulating layers, are sequentially stacked on the second interlayer insulating layer 162.

The functional layer FL may be disposed on the third organic layer 183, and the cathode (Cathode) may be disposed thereon.

The encapsulation layer 400 is disposed on the cathode (Cathode), and the sensing insulating layers 501, 510, and 511 are sequentially disposed thereon. The encapsulation layer 400 may have a triple-layer structure sequentially including an inorganic encapsulation layer, an organic encapsulation layer, and an inorganic encapsulation layer. In addition, all of the sensing insulating layers 501, 510, and 511 may be inorganic insulating layers.

The planarization layer 550 may be disposed on the sensing insulating layers 501, 510, and 511.

The metal layer, the first semiconductor layer, the first gate conductive layer, the second gate conductive layer, the oxide semiconductor layer, the third gate conductive layer, the first data conductive layer, the second data conductive layer, and the anode are not disposed in the first component area EA1 as described above. In addition, the light emitting layer EML and the sensing electrodes 540 and 541 are not formed therein.

Also, in the first photosensor area OPS1 of the first component area EA1, additional openings OP-1, OPSL-1, and OPCF-1 are formed in the pixel defining layer 380, the scattering layer 210, and the light blocking area of the color filter, respectively, so that the pixel defining layer 380 and the color filter may not be formed. As a result, light may be transmitted through the first photosensor area OPS1. In contrast, since the additional openings OP-1, OPSL-1, and OPCF-1 are not disposed in the second photosensor area OPS2 of the first component area EA1, light may not be transmitted and scattered by overlap the pixel defining layer 380, the scattering layer 210, and the light blocking area of the color filter.

In the above, the embodiment in which a total of three organic layers are formed and the anode connecting opening is formed in the second organic layer and the third organic layer has been described. However, at least two organic layers may be formed, and in this case, the anode connecting opening may be disposed in the upper organic layer disposed far from the substrate, and the lower organic layer opening may be disposed in the lower organic layer.

FIG. 26 and FIG. 27 illustrate embodiments in which the scattering layer 210 further includes an inner opening OPSLu. FIG. 26 illustrates an embodiment in which the scattering layer 210 further includes the inner opening OPSLu in the embodiment of FIG. 24, and FIG. 27 illustrates an embodiment in which the scattering layer 210 further includes the inner opening OPSLu in the embodiment of FIG. 25.

In the embodiments of FIG. 26 and FIG. 27, the inner opening OPSLu of the scattering layer 210 is a portion where the scattering layer 210 is not formed in a portion of the region where the light blocking area of the light blocking layer 220 or the color filter 230 is disposed. Due to the inner opening OPSLu of the scattering layer 210, the light blocking area of the light blocking layer 220 or the color filter 230 has a structure that directly contacts a layer disposed below the scattering layer 210, that is, the third sensing insulating layer 511, through the inner opening OPSLu of the scattering layer 210.

Even in the embodiments of FIG. 26 and FIG. 27, the opening OPSL of the scattering layer 210 may also have the edge position range described in FIG. 10 to eliminate or weaken rainbow mura so that it is not visible.

According to the embodiments, an opening is formed in at least one scattering layer disposed in a display area of a light emitting display device, thereby eliminating rainbow mura caused by interference between external light and the scattering layer and the anode.

According to the embodiments, since the polarizing plate is not used, the luminance does not decrease while passing through the polarizing plate so that the maximum luminance value of the light emitting display device is formed to be 2500 nits or more, thereby providing a bright light emitting display device.

Each of the embodiments provided in the above description is not excluded from being associated with one or more features of another example or some embodiments also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A light emitting display device comprising:
a substrate;
an anode on the substrate;
a pixel defining layer comprising a first opening above the anode;
a light emitting layer in the first opening;
a cathode on the light emitting layer and the pixel defining layer;
an encapsulation layer on the cathode;
a scattering layer on the encapsulation layer, the scattering layer comprising scattering particles, and a scattering layer opening that at least partially overlaps the first opening in plan view; and
a light blocking layer comprising a second opening that overlaps the first opening in plan view,
wherein, in plan view, a width of the scattering layer opening is smaller than a width of the second opening by 1 µm or more, and the width of the scattering layer opening is smaller than a width of the first opening by 10 µm or less.

2. The light emitting display device of claim 1, wherein, in plan view, the first opening, the scattering layer opening, and the second opening are circular.

3. The light emitting display device of claim 1, wherein, in plan view, the first opening, the scattering layer opening, and the second opening are elliptical.

4. The light emitting display device of claim 3, wherein a major axis direction of the scattering layer opening matches major axis directions of the first opening and the second opening.

5. The light emitting display device of claim 4, wherein, in plan view, the width of the scattering layer opening is equal to the width of the first opening.

6. The light emitting display device of claim 1, wherein the scattering layer further comprises an inner opening in which the scattering layer is not formed in a portion where the light blocking layer is provided.

7. The light emitting display device of claim 1, wherein the scattering layer comprises a sidewall that protrudes at an acute angle toward a front surface of the light emitting display device, and
wherein a taper angle of the scattering layer is less than 90 degrees.

8. A light emitting display device comprising:
a substrate;
an anode on the substrate;
a pixel defining layer comprising a first opening above the anode;
a light emitting layer in the first opening;
a cathode on the light emitting layer and the pixel defining layer;
an encapsulation layer on the cathode;
a scattering layer on the encapsulation layer, the scattering layer comprising scattering particles and a scattering layer opening that at least partially overlaps the first opening in plan view; and
a plurality of color filters on the scattering layer and respectively corresponding to different colors,
wherein at least two of the plurality of color filters overlap,
wherein the light emitting display device comprises a second opening that overlaps the first opening and in which only one of the plurality of color filters is provided, and
wherein, in plan view, a width of the scattering layer opening is smaller than a width of the second opening by 1 µm or more, and the width of the scattering layer opening is smaller than a width of the first opening by 10 µm or less.

9. The light emitting display device of claim 8, wherein, in plan view, the first opening, the scattering layer opening, and the second opening are circular.

10. The light emitting display device of claim 8, wherein, in plan view, the first opening, the scattering layer opening, and the second opening are elliptical.

11. The light emitting display device of claim 10, wherein a major axis direction of the scattering layer opening matches major axis directions of the first opening and the second opening.

12. The light emitting display device of claim 11, wherein, in plan view, the width of the scattering layer opening is equal to the width of the first opening match.

13. The light emitting display device of claim 8, wherein the scattering layer further comprises an inner opening in which the scattering layer is not formed in a portion where a light blocking area of the plurality of color filters is disposed.

14. The light emitting display device of claim 8, wherein the scattering layer comprises a sidewall that protrudes at an acute angle toward a front surface of the light emitting display device, and
wherein a taper angle of the scattering layer is less than 90 degrees.

15. An electronic device comprising:
a light emitting display device configured to display an image,
wherein the light emitting display device comprises:
a substrate;
an anode on the substrate;
a pixel defining layer comprising a first opening above the anode;
a light emitting layer in the first opening;
a cathode on the light emitting layer and the pixel defining layer;
an encapsulation layer on the cathode;
a scattering layer on the encapsulation layer, the scattering layer comprising scattering particles and a scattering layer opening that at least partially overlaps the first opening in plan view; and
a second opening overlapping the first opening in plan view, and
wherein, in plan view, a width of the scattering layer opening is smaller than a width of the second opening by 1 µm or more, and the width of the scattering layer opening is smaller than a width of the first opening by 10 µm or less.

16. The electronic device of claim 15, further comprising a light blocking layer on the scattering layer and comprising the second opening.

17. The electronic device of claim 15, further comprising a plurality of color filters on the scattering layer and respectively corresponding to different colors,
wherein at least two or more of the plurality of color filters overlap in a light blocking area of the plurality of color filters, and
wherein only one of the plurality of color filters is in the second opening.

18. The electronic device of claim 15, wherein, in plan view, the first opening, the scattering layer opening, and the second opening are circular or elliptical.

19. The electronic device of claim 15, further comprising a light blocking layer comprising the second opening,
wherein the scattering layer further comprises an inner opening in which the scattering layer is not formed in a portion where the light blocking layer is provided.

20. The electronic device of claim 15, wherein the scattering layer comprises a sidewall that protrudes at an acute angle toward a front surface of the light emitting display device, and
wherein a taper angle of the scattering layer is less than 90 degrees.
